(19) United States
(12) Patent Application Publication
(10) Pub. No.: US 2013/0177851 A1
(43) Pub. Date: Jul. 11, 2013

(54) PHOTORESIST COMPOSITION

(71) Applicant: SUMITOMO CHEMICAL COMPANY, LIMITED, Tokyo (JP)

(72) Inventors: Maki KAWAMURA, Osaka-shi (JP); Tatsuro MASUYAMA, Osaka-shi (JP)

(73) Assignee: SUMITOMO CHEMICAL COMPANY, LIMITED, Tokyo (JP)

(21) Appl. No.: 13/714,488

(22) Filed: Dec. 14, 2012

(30) Foreign Application Priority Data
Dec. 19, 2011 (JP) 2011-277189

(51) Int. Cl. G03F 7/027

(52) U.S. Cl. CPC G03F 7/027
USPC 430/284.1; 430/325

(57) ABSTRACT

A photoresist composition comprising
a resin which is selected from the group consisting of (meth)acryl resins and poly(hydroxystylene) resins,
a novolak resin,
an acid generator, and
a compound represented by formula (X1):

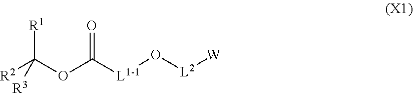

and a solvent.

This nonprovisional application claims priority under 35 U.S.C. §119(a) on Patent Application No. 2011-277189 filed in JAPAN on Dec. 19, 2011, the entire contents of which are hereby incorporated by reference.

### FIELD OF THE INVENTION

The present invention relates to a photoresist composition and a method for producing a photoresist pattern.

### BACKGROUND OF THE INVENTION

The production of bumps for semiconductor requires photoresist compositions capable of forming a thick photoresist film or photoresist pattern on the film.

As to photoresist compositions for preparing a thick photoresist film or photoresist pattern on the film, JP2008-249993A1 mentions a positive type chemically amplified photoresist composition which comprises

(A) a polymer comprising 10 to 70% by mole of polymer unit derived from t-butyl(meth)acrylate and 30 to 90% by mole of polymer unit derived from a compound represented by formula
(I); R¹—(C═CH₂)—(C═O)—O—R², said polymer having weight average molecular weight of 50000 to 300000,
(B) an alkaline-soluble polymer, and
(C) photosensitive acid generator.

### SUMMARY OF THE INVENTION

The present application provides the inventions as follow.
[1] A photoresist composition comprising:

a resin which is selected from the group consisting of (meth)acryl resins and poly(hydroxystylene) resins;

a novolak resin;

an acid generator;

a compound represented by formula (X1):

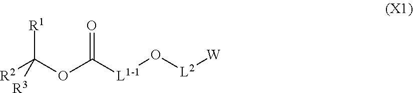

wherein R¹, R² and R³ each independently represent a hydrogen atom, a C1-C12 alkyl group, a C3-C12 alicyclic hydrocarbon group, a C6-C30 aryl group, or a C7-C31 aralkyl group, or two of R¹, R² and R³ are bonded to each other to represent a C2-C10 divalent aliphatic hydrocarbon group,
L¹⁻¹ represents a group represented by formula (X1-1):

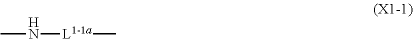

where L^{1-1a} represents a single bond, a C1-C30 hydrocarbon group which optionally has a substituent selected from a hydroxyl group, an amino group or a mercapto group and in which a methylene group is optionally replaced by an oxygen atom, an imino group, a sulfur atom or a carbonyl group, or a group represented by formula (X1-2):

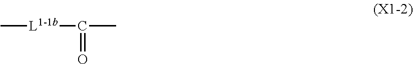

where L^{1-1b} represents a C2-C10 heterocyclic ring having one nitrogen atom bonded to —C(═O)— of the moiety —C(═O)-L¹⁻¹- in formula (X1) and having a carbon atom attached to the nitrogen atom and to the carbon atom of the carbonyl group of formula (X1-2),
L² represents a single bond, or a C1-C12 saturated aliphatic hydrocarbon group, and
W represents a C6-C30 aromatic hydrocarbon group which optionally has a substituent; and a solvent.
[2] The photoresist composition according to [1], wherein L¹⁻¹ represents a group represented by formula (X1-1) where L^{1-1a} represents a single bond, a C6-C10 aromatic hydrocarbon group, a C3-C10 alicylcic hydrocarbon group, or a C1-C30 aliphatic hydrocarbon group in which a methylene group is optionally replaced by an oxygen atom, a sulfur atom or a carbonyl group and in which a hydrogen atom is optionally replaced by a C6-C30 aryl group or a C7-C31 aralkyl group.
[3] The photoresist composition according to [1] or [2], wherein the compound represented by formula (X1) is a compound represented by formula (X):

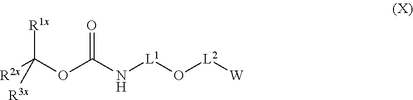

wherein L² and W are the same as defined in [1],
R^{1X}, R^{2X} and R^{3X} each independently represent a hydrogen atom, a C1-C12 alkyl group, a C3-C12 alicyclic hydrocarbon group, a C6-C30 aryl group, or a C7-C31 aralkyl group, and
L¹ represents a single bond, or a C1-C30 saturated aliphatic hydrocarbon group where a methylene group is optionally replaced by an oxygen atom, a sulfur atom or a carbonyl group and where a hydrogen atom is optionally replaced by a C6-C30 aryl group or a C7-C31 aralkyl group.
[4] The photoresist composition according to [3], wherein R^{1X}, R^{2X} and R^{3X} each independently represent a hydrogen atom, or a C1-C3 alkyl group,
L¹ represents a single bond, or a C1-C5 saturated aliphatic hydrocarbon group where a methylene group is optionally replaced by a carbonyl group and where a hydrogen atom is optionally replaced by a C7-C10 aralkyl group,
L² represents a single bond or a methylene group, and
W represents a group of formula (X2):

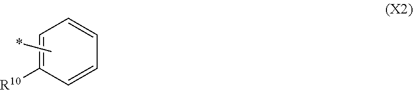

where R¹⁰ represents a hydrogen atom or a nitro group, and
* is a binding position to L².
[5] The photoresist composition according to [3] or [4], wherein the compound represented by formula (X) is one represented by formula (X1-A), (X1-B) or (X1-C):

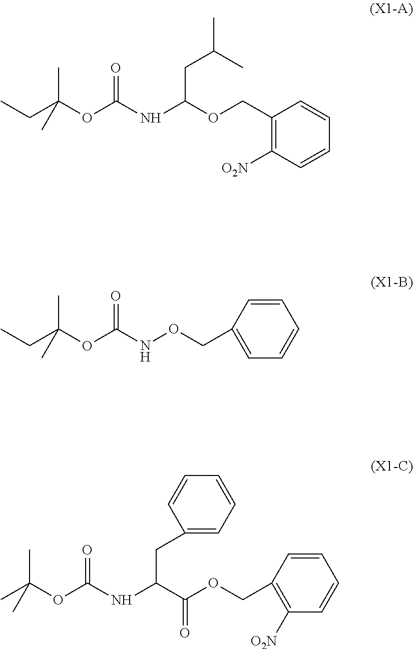 [SMILES: CCC(C)(C)OC(=O)NC(CC(C)C)OCc1ccccc1[N+](=O)[O-] ; CCC(C)(C)OC(=O)NOCc1ccccc1 ; CC(C)(C)OC(=O)NC(Cc1ccccc1)C(=O)OCc1ccccc1[N+](=O)[O-]]

[6] A process for producing a photoresist pattern comprising:

(1) a step of applying the photoresist composition according to any one of [1] to [5] on a substrate to form a photoresist composition film,

(2) a step of forming a photoresist film by drying the photoresist composition film,

(3) a step of exposing the photoresist film to radiation,

(4) a step of heating the photoresist film after exposing, and

(5) a step of developing the heated photoresist film.

[7] The process according to [6] wherein the substrate comprises a conductive material containing copper or an alloy comprising the copper.
[8] The process according to [6] or [7] wherein the photoresist film is exposed with g ray, h ray or i ray.
[9] A photoresist film obtained by applying the photoresist composition according to any one of [1] to [5] on a substrate, followed by drying the composition wherein the thickness of said film is in the range from 4 to 150 μm.

### BRIEF DESCRIPTION OF THE DRAWINGS

FIG. 1(a) shows the profile of a photoresist pattern that is rectangle at both its top and bottom sites.

FIG. 1(b) shows the profile of a photoresist pattern that is round shape at its top site.

### DESCRIPTION OF THE PREFERRED INVENTION

The photoresist composition of the present invention (hereinafter, such composition is briefly referred to as “the composition of the present invention”) comprises:

a resin which is selected from the group consisting of (meth)acryl resins and poly(hydroxystylene) resins;

a novolak resin;

an acid generator;

a compound represented by formula (X1):

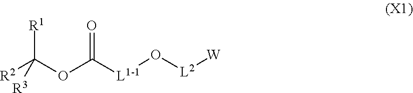

and a solvent.

The composition of the present invention comprises these components, so that it can provide a thick photoresist film and a photoresist pattern with excellent profile. Moreover, the composition of the present invention can provide such an excellent photoresist pattern as mentioned above even after storage for a long term.

The composition of the present invention comprises

a resin which is selected from the group consisting of (meth)acryl resins and poly(hydroxystylene) resins, and

a novolak resin.

The resin which is selected from the group consisting of (meth)acryl resins and poly(hydroxystylene) resins is generally one insoluble or poorly soluble in an aqueous alkali solution but becoming soluble in an aqueous alkali solution by the action of an acid. Herein, “soluble in an aqueous alkali solution by the action of an acid” means such property as soluble in an aqueous alkali solution by contacting it with into an acid while hardly soluble or insoluble in an aqueous alkali solution before contacting it with into an acid.

Hereinafter, the resin which is selected from the group consisting of (meth)acryl resins and poly(hydroxystylene) resins is simply referred to as “Resin (A)”.

When Resin (A) is one soluble in an aqueous alkali solution by the action of an acid, the resin generally comprises a structural unit having an acid-labile group. Herein “an acid-labile group” refers to a group capable of being cleaved in case of contacting with an acid to give a hydrophilic group such as a hydroxy group or carboxy group.

Examples of the acid-labile group include a group represented by the formula (1):

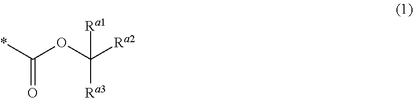

wherein R^{a1}, R^{a2} and R^{a3} independently each represent a C1-C8 alkyl group, a C3-C20 alicyclic hydrocarbon group or a combination of them, or R^{a1} and R^{a2} can be bonded each other to form a C2-C20 divalent aliphatic hydrocarbon group, and * represents a binding position.

Examples of the C1-C8 alkyl group include a methyl group, an ethyl group, a propyl group, a butyl group, a pentyl group, a hexyl group, a heptyl group, and an octyl group.

The alicyclic hydrocarbon group may be monocyclic or polycyclic, which includes a cycloalkyl group such as cyclopentyl group, cyclohexyl group, cycloheptyl group, and cyclooctyl group; and polycyclic alicyclic hydrocarbon group such as decahydronaphtyl group, adamantyl group, norbornyl group and the groups represented as follow.

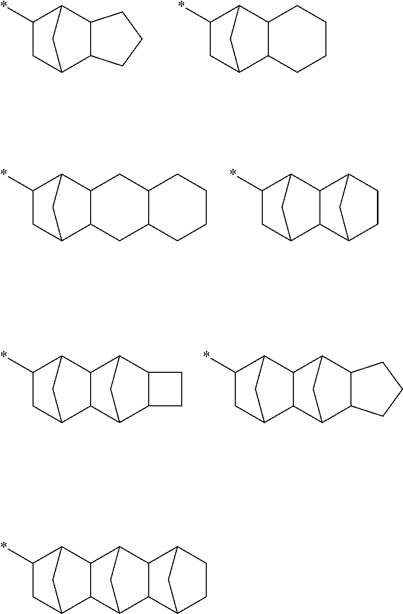

in which * represents a binding position.

The combination of alkyl group and alicyclic hydrocarbon group includes methylcyclohexyl group, dimethylcyclohexyl group, and methylnorbornyl group.

The divalent aliphatic hydrocarbon group formed by R^{a1} and R^{a2} which have bound each other has preferably C3-C12 carbon atoms.

When R^{a1} and R^{a2} are bonded each other to form a ring together with a carbon atom to which R^{a1} and R^{a2} are bonded, examples of the group represented by —C(R^{a1})(R^{a2})(R^{a3}) include the following groups.

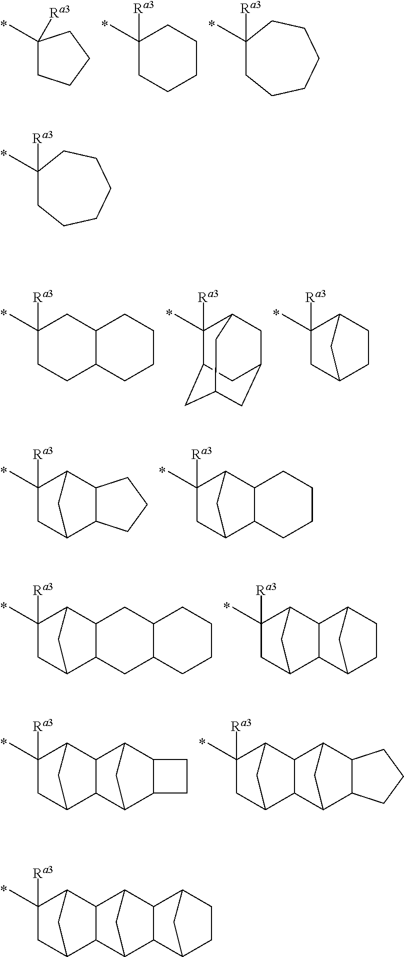

wherein R^{a3} is the same as defined above, and * represents a binding position.

The group represented by the formula (1) includes a group represented by formula (1-1), formula (1-2), formula (1-3) or formula (1-4).

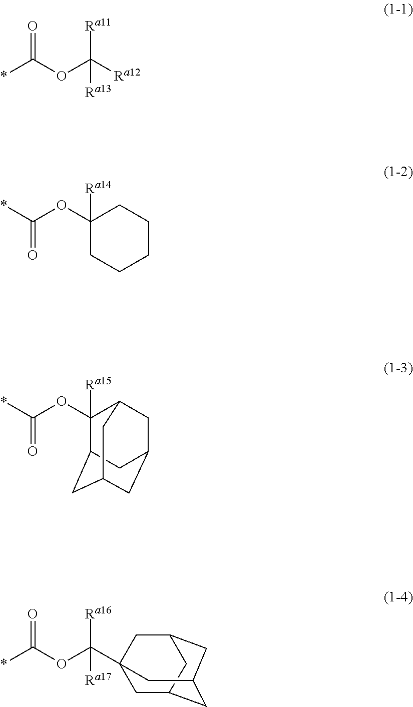

in which R^{a11}, R^{a12}, R^{a13}, R^{a14}, R^{a15}, R^{a16} and R^{a17} independently each represent a C1-C8 alkyl group.
The group represented by the formula (1) includes preferably tert-butoxycarbonyl group, 1-ethylcyclohexane-1-yloxycarbonyl group, 1-ethyladamantane-2-yloxycarbonyl group, and 2-isopropyladamantane-2-yloxycarbonyl group.

Among them, preferred are those represented by formula (1-1).

Examples of the acid-labile group include a group represented by the formula (2):

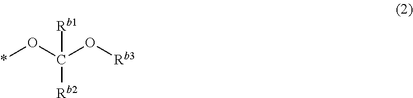

wherein R^{b1} and R^{b2} independently each represent a hydrogen atom or a C1-C12 monovalent hydrocarbon group, and R^{b3} represents a C1-C20 monovalent hydrocarbon group, and R^{b2} and R^{b3} can be bonded each other to form a C2-C20 divalent hydrocarbon group, and a methylene group in the hydrocarbon group and the ring can be replaced by —O— or —S—, and* represents a binding position, provided that the group represented by the formula (2) does not attach to a carbon atom of carbonyl group.

Examples of the hydrocarbon group include an alkyl group, an alicyclic hydrocarbon group and an aromatic hydrocarbon group. Examples of the alkyl group for formula (2) include a methyl group, an ethyl group, a propyl group, a butyl group, a pentyl group, a hexyl group, a heptyl group, an octyl group, a decyl group, and a dodecyl group.

Examples of the alicyclic hydrocarbon group for formula (2) include those as mentioned above.

Examples of the aromatic hydrocarbon group include an aryl group such as a phenyl group, a naphthyl group, an anthryl group, a biphenyl group, a phenanthryl group and a fluorenyl group, which include those having a C1-C8 alkyl group.

It is preferred that at least one of R^{b1} and R^{b2} is a hydrogen atom.

Examples of the group represented by the formula (2) include the following;

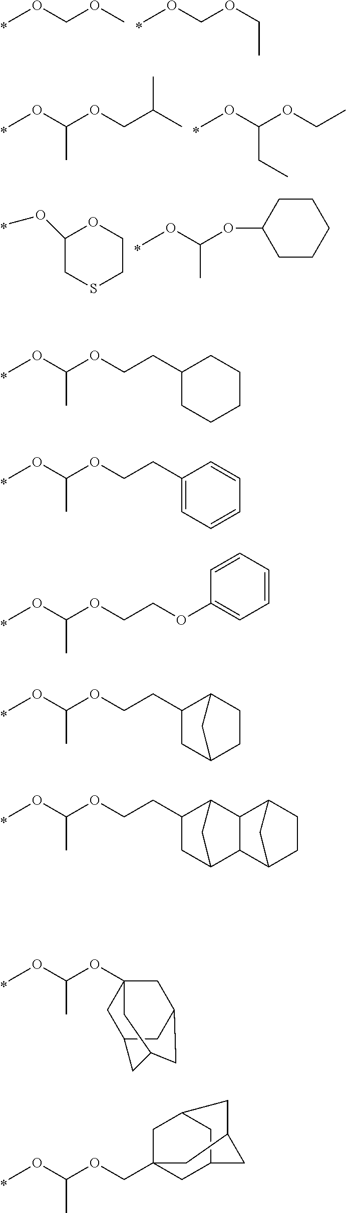

where * represents a binding position.

The structural unit having an acid-labile group is preferably one derived from a monomer having an acid-labile group in its side chain and a carbon-carbon double bond, and is more preferably one derived from a (meth)acrylate monomer having an acid-labile group in its side chain and one derived from a styrene monomer having an acid-labile group in its side chain.

The (meth)acryl resin of Resin (A) generally comprises a structural unit derived from a (meth)acrylate monomer having the group represented by the formula (1).

Examples of the (meth)acrylate monomer having the group represented by the formula (1) include the compound of the formula (1-1-1).

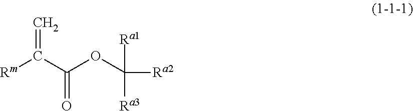

where R^{m} represents a hydrogen atom or a methyl group, and R^{a1}, R^{a2} and R^{a3} are as defined above.

The poly(hydroxystylene) resins of Resin (A) generally comprise a structural unit derived from a styrene compound having an acid-labile group.

The structural unit derived from a styrene compound having an acid-labile group typically comprises a side chain in which a phenolic hydroxyl group has been protected with a protecting group capable of being removed by action of an acid. The structural unit derived from a styrene compound having an acid-labile group is typically represented by formula (S).

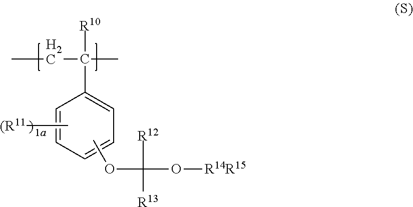

in which R¹⁰ represents a hydrogen atom, a halogen atom, or a C1-C6 alkyl group optionally having a halogen atom,
l^{a} represents an integer of 0 to 4,
R¹¹ represents independently in each occurrence a halogen atom, a hydroxy group, a C1-C6 alkyl group, a C1-C6 alkoxy group, a C2-C4 acyl group, a C2-C4 acyloxy group, an acryloyl group or a methacryloyl group,
R¹² and R¹³ independently in each occurrence represent a hydrogen atom or C1-C12 hydrocarbon group,
R¹⁴ represents a single bond or a C1-C12 alkylene group where a methylene group may be replaced by an oxygen atom, a sulfur atom, a carbonyl group, a sulfonyl group, or —N(R^{c})— where R^{c} represents a hydrogen atom or a C1-C6 alkyl group, and R¹⁵ represents a C1-C18 hydrocarbon group optionally having a substituent.

In formula (S), the hydrocarbon group includes a C1-C18 alkyl group such as a methyl group, an ethyl group, a propyl group, a butyl group, a pentyl group, a hexyl group, a heptyl group, an octyl group, a decyl group, and a dodecyl group;

a C3-C18 cycloalkyl group such as a cyclopropyl group, a cyclobutyl group, a cyclopentyl group, a cyclohexyl group, a cycloheptyl group, a cyclooctyl group, a cyclodecyl group, a cyclododecyl group and an adamantyl group; and

a C6-C18 aryl group such as a phenyl group, a naphthyl group, an anthryl group, biphenyl group, phenanthryl group, fluorenyl group.

The substituent for the hydrocarbon group in formula (S) includes the same groups as explained regarding R^{1a}, R^{2a}, R^{3a}, R^{4a}, R^{5a}, R^{6a}, R^{7a} and R^{8a}.

The (meth)acryl resins of Resin (A) generally further comprise a structural unit having no acid-labile group, such as a structural unit derived from a (meth)acrylate having no acid-labile group. The (meth)acryl resins of Resin (A) is described in JP2008-249993A1.

Examples of the (meth)acrylates having no acid-labile group include a compound represented by formula (I);

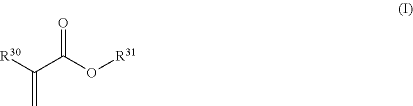

in which R³⁰ represents a hydrogen atom or a methyl group, R³¹ represents a group of formula (II);

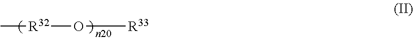

in which R³² represents C1-C6 alkanediyl group, R³³ represents C1-C6 alkyl group or C3-C10 cycloalkyl group, and n represent an integer of 1 to 30.
In formulae (I) and (II), the alkyl group includes a methyl group, an ethyl group, a propyl group, a butyl group, a pentyl group, and a hexyl group, preferably C1-C4 alkyl group. The cycloalkyl group includes a cyclopentyl group, a cyclohexyl group, a cycloheptyl group, a cyclooctyl group, and an adamantyl group, preferably C6-C10 cycloalkyl group.
In formula (II), the alkanediyl group includes a methylene group, an ethylene group, a propylene group, a butylene group, a pentylene group, and a hexylene group.

The n is preferably an integer of 2 to 16, more preferably an integer of 2 to 8. When the group of formula (II) has two or more moieties represented by —R³²—O—, the moieties may be the same as or different from each other.

Examples of the compound represented by formula (I) include
ethylenegrylcolmonomethylether(meth)acrylate,
ethylenegrylcolmonoethylether(meth)acrylate,
ethylenegrylcolmonopropylether(meth)acrylate,
ethylenegrylcolmonombutylether(meth)acrylate,
diethylenegrylcolmonomethylether(meth)acrylate,
triethylenegrylcolmonomethylether(meth)acrylate,
tetraethylenegrylcolmonomethylether(meth)acrylate,
pentaethylenegrylcolmonobutylether(meth)acrylate,
hexaethylenegrylcolmonomethylether(meth)acrylate,
nonaethylenegrylcolmonomethylether(meth)acrylate,
octaethylenegrylcolmonomethylether(meth)acrylate, or
polyethylenegrylcolmonomethylether(meth)acrylate.

Among them, the compound represented by formula (I) is preferably of the formula in which R³¹ represents a group of formula (II).

Resin (A) may comprise other structural units having no acid-labile group than the structural unit mentioned above. Examples of other structural units include those derived from styrene-containing compounds.

The styrene-containing compounds include one from which a structural unit of the following formula is derived;

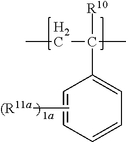

where R¹⁰ and l^{a} are as defined above, and

R^{11a} represents independently in each occurrence a hydrogen atom, a halogen atom, a hydroxy group, a C1-C6 alkyl group, a C1-C6 alkoxy group, a C2-C4 acyl group, a C2-C4 acyloxy group, an acryloyl group or a methacryloyl group.

Examples of the styrene-containing compound specifically include hydroxystyrene.

Examples of Resin (A) preferably include

the resin which comprises a structural unit derived from tert-butyl(meth)acrylate and a structural unit derived from the compound represented by formula (I) in which R² represents a group of formula (II), and

the resin which comprises a structural unit represented by the formula (S),

more preferably the resin which comprises a structural unit derived from tert-butyl(meth)acrylate and a structural unit derived from the compound represented by formula (I) in which R² represents a group of formula (II).

Examples of Resin (A) specifically include a copolymer of tert-butyl(meth)acrylate, octaethylenegrylcolmonomethylether(meth)acrylate and diethylenegrylcolmonomethylether(meth)acrylate.

The weight average molecular weight of Resin (A) is generally from 5000 to 300000 determined by gel permeation chromatography using polystyrene as the standard.

The weight average molecular weight of (meth)acrylate resins of Resin (A) is generally from 5000 to 300000, preferably from 50000 to 300000, more preferably from 100000 to 250000, still more preferably from 100000 to 200000, determined by gel permeation chromatography using polystyrene as the standard.

The weight average molecular weight of poly(hydroxystylene) resins of Resin (A) is more preferably from 5000 to 60000, still more preferably from 10000 to 25000, determined by gel permeation chromatography using polystyrene as the standard.

The composition of the present invention further comprises a novolak resin.

The novolak resin can be produced by condensing a phenolic compound with an aldehyde in the presence of a catalyst.
The phenolic compound includes phenol; o-, m- or p-cresol; 2,3-, 2,5-, 3,4- or 3,5-xylenol; 2,3,5-avianmethylphenol, 2-, 3- or 4-tert-butylphenol; 2-tert-butyl-4- or 5-methylphenol; 2-, 4- or 5-methylresorcinol; 2-, 3- or 4-methoxyphenol; 2,3-, 2,5- or 3,5-dimethoxyphenol; 2-methoxyresorcinol; 4-tert-butylcatechol; 2-, 3- or 4-ethylphenol; 2,5- or 3,5-diethylphenol; 2,3,5-triethylphenol; 2-naphthol; 1,3-, 1,5- or 1,7-dihydroxynaphthalene; and polyhydroxytriphenylmethane compounds obtained by condensation with xylenol and hydroxybenzaldehyde.
One or more phenolic compounds can be employed for producing the novolak resin.
Among them, preferred are o-cresol, m-cresol, p-cresol, 2,3-xylenol, 2,5-xylenol, 3,4-xylenol, 3,5-xylenol, 2,3,5-avianmethylphenol, 2-t-butylphenol, 3-t-butylphenol, 4-t-butylphenol, 2-t-butyl-4-methylphenol, 2-t-butyl-5-methylphenol.
The aldehyde includes aliphatic aldehydes such as formaldehyde, acetaldehyde, propionaldehyde, n-butyraldehyde, isobutyraldehyde acrolein or croton aldehyde; alicyclic aldehydes such as cyclohexane aldehyde, cyclopentane aldehyde, furfuraldehyde or furylacrolein; aromatic aldehydes such as benzaldehyde, o-, m- or p-methylbenzaldehyde, p-ethylbenzaldehyde, 2,4-, 2,5-, 3,4- or 3,5-dimethylbenzaldehyde or o-, m- or p-hydroxybenzaldehyde; and aldehydes such as phenyl acetaldehyde or cinnamaldehyde, preferably formaldehyde because of its availability.
The catalyst to be used for condensation of the phenolic compound with aldehydes includes inorganic acids such as hydrochloric acid, sulfuric acid, perchloric acid or phosphoric acid; and organic acids such as formic acid, acetic acid, oxalic acid, trichloroacetic acid or p-toluenesulfonic acid; and salts of divalent metal, such as zinc acetate, zinc chloride or acetic acid magnesium.
Two or more catalysts may be employed together for the condensation.
The catalyst is generally used in an amount of from 0.01 to 1 mol per mol of aldehyde.
The condensation reaction of phenolic compound with aldehyde may be conducted in a known manner.
For example, the reaction can be carried out by mixing phenolic compound and aldehyde, at temperature in the range of 60 to 120° C., in a suitable solvent to react them, for 2 to 30 hours. After the reaction end, novolak resins can be separated by washing the reaction mixture with water, and concentrating it. If necessary, water-insoluble solvents may be added to the reaction mixture before washing the mixture with water.

The weight average molecular weight of novolak resins is not limited to specific range, preferably from 5000 to 50000 determined by polystyrene as the standard.

The mass ratio of Resin (A) to novolak resin is preferably 1/4 to 4/1, more preferably 1/2 to 3/2.

The total content of Resin (A) and novolak resin is preferably 5 to 60% by weight, more preferably 25 to 60% by weight, of the total amount of the composition of the present invention.

The composition of the present invention may further comprise another resin in addition to Resin (A) and novolak resin.

Examples of another resin include known resins which have been used for a general photoresist composition, specifically include a polymer which comprises a structural unit derived from novolak resin and a structural unit derived from poly(hydroxystyrene) and has cross-linking structure derived from a vinyl ether compound. Hereinafter, the polymer which comprises a structural unit derived from novolak resin and a structural unit derived from poly(hydroxystyrene) and has cross-linking structure derived from a vinyl ether compound is referred to as “resin (A4)”.

The novolak resin is usually produced by a reaction of a phenol compound and an aldehyde compound in the presence of an acid catalyst, as described above.

Examples of the poly(hydroxystyrene) include poly(o-hydroxystyrene), poly(m-hydroxystyrene) and poly(p-hydroxystyrene), preferably poly(p-hydroxystyrene). As the poly(hydroxystyrene), a commercially available one may be used and one produced according to a known method may be used.

As the vinyl ether compound, a compound having two vinyl ether structures may be used and a compound having more than three vinyl ether structures may be used. The compound having two vinyl ether structures is preferable. Herein, “the vinyl ether structure” means the following structure:

—CH₂—O—CH═CH₂.

Specific examples of the vinyl ether compound include
1,4-bis(vinyloxymethyl)cyclohexane and
1,2-bis(vinyloxy)ethane, and
1,4-bis(vinyloxymethyl)cyclohexane is preferable.
   As the vinyl ether compound, a commercially available one is usually used.

The resin (A4) can be produced by reacting the novolak resin, the poly(hydroxystyrene) and the vinyl ether compound in the presence of an acid catalyst, as mentioned in US2008/0153036A1.

When the composition of the present invention further comprise another resin in addition to Resin (A) and novolak resin, the total amount of Resin (A) and novolak resin is preferably 50% by mass or more, more preferably 80% by mass or more, of the total amount of the resins in the photoresist composition.

The total amount of resins in the composition of the present invention is preferably 5 to 60% by mass of the total amount of the composition.

The composition of the present invention comprises an acid generator.
The acid generator is a compound which can be decomposed by light or radiation to generate an acid. The composition of the present invention can provide a photoresist pattern because the resin of the composition is decomposed by an acid generated from the acid generator.
The acid generators may be either ionic or non-ionic one. The acid generator can be used singly or as a mixture of two or more thereof.
Examples of the acid generators include onium salts, halogen compounds, diazoketone compounds, sulfone compounds and sulfonic acid compounds. The acid generator is preferably a sulfone compound or a sulfonic acid compound. The sulfone compound or sulfonic acid compound preferably comprises a sulfonium cation, a sulfonate anion, or both of them.
Examples of the ionic acid generators include the compounds of formulae (Va), (Vb), (Vc) and (III);

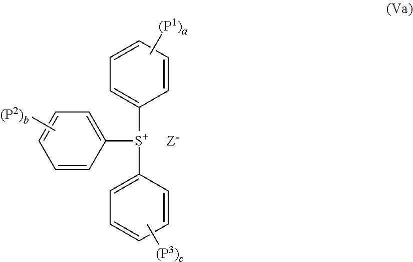

where P¹, P² and P³ independently each represents a hydrogen atom, a hydroxyl group, C1-C6 alkyl group or C1-C6 alkoxy group, a, b and c independently each represents an integer of 0 to 3, and Z⁻ represents an organic counter ion,

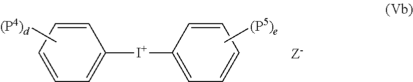

where P⁴ and P⁵ independently each represents a hydrogen atom, a hydroxyl group, C1-C6 alkyl group or C1-C6 alkoxy group, d and e independently each represents an integer of 0 or 1, and Z⁻ represents an organic counter ion,

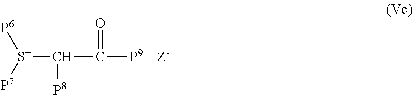

where P⁶ and P⁷ independently each represents C1-C6 alkyl group or C3-C10 cycloalkyl group, or P⁶ and P⁷ are bonded each other to form, together with S⁺, a C3-C7 hydrocarbon ring where a methylene group has been replaced by a carbonyl group, an oxygen atom or a sulfur atom;
P⁸ represents a hydrogen atom;
P⁹ represents C1-C6 alkyl group, C3-C10 cycloalkyl group, or an aromatic hydrocarbon group optionally having a substituent, or P⁸ and P⁹ are bonded each other to form, together with a carbon atom, a hydrocarbon ring, and
Z⁻ represents an organic counter ion;

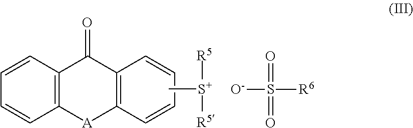

where A represents an oxygen atom or a sulfur atom,
R⁵ and R⁵′ independently each represents a methyl group or a phenyl group,
R⁶ represents a C1-C8 perfluoroalkyl group,
and Z⁻ represents an organic counter ion.
In formulae (Va), (Vb), (Vc) and (III), the C1-C6 alkyl group includes a methyl group, an ethyl group, a propyl group, a butyl group, a pentyl group, and a hexyl group. The C3-C10 cycloalkyl group includes a cyclopentyl group, a cyclohexyl group, a cycloheptyl group and a cyclooctyl group. The aromatic hydrocarbon group includes a phenyl group, a naphthyl group, an anthryl group, a p-methylphenyl group, a p-tert-butylphenyl group and a p-adamantylphenyl group. The C1-C8 perfluoroalkyl group includes a trifluoromethyl group, a pentafluoroethyl group, a heptafluoropropyl group, a nonafluorobutyl group, an undecafluoropentyl group and a tridecafluorohexyl group.
Examples of the cation moiety of formula (Va) specifically include the moieties as follow.

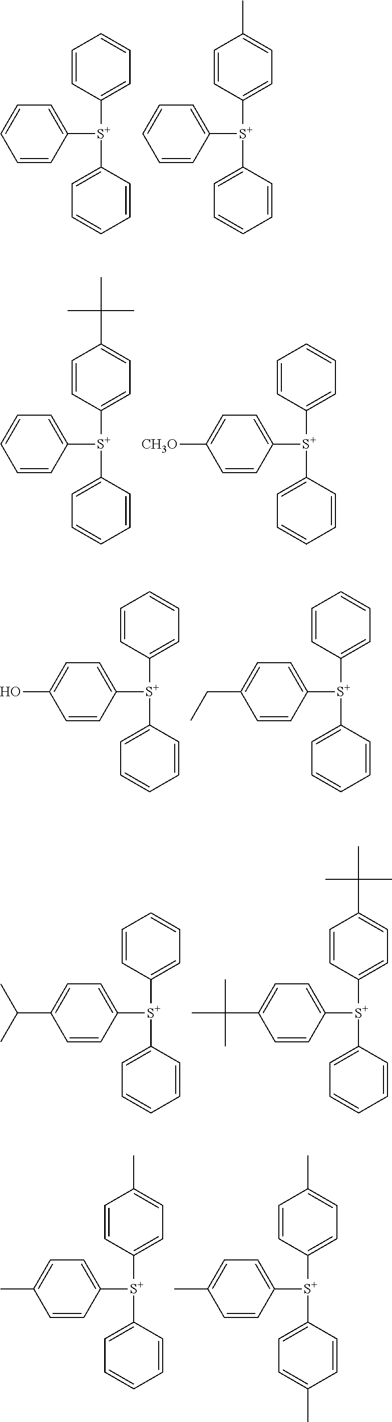

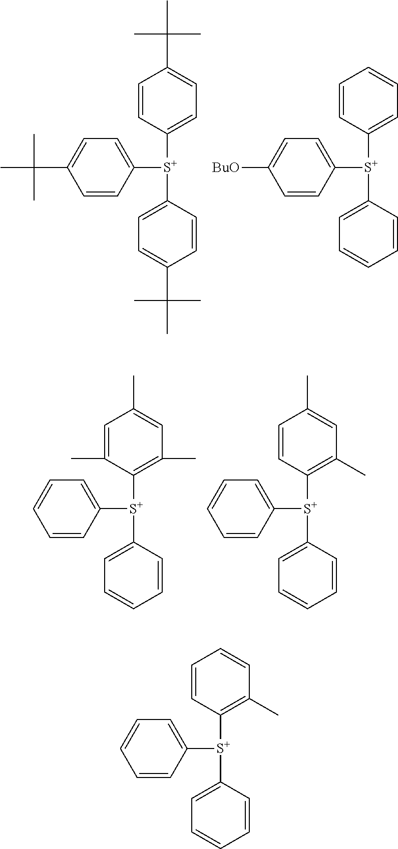

Examples of the cation moiety of formula (Vb) specifically include the moieties as follow.

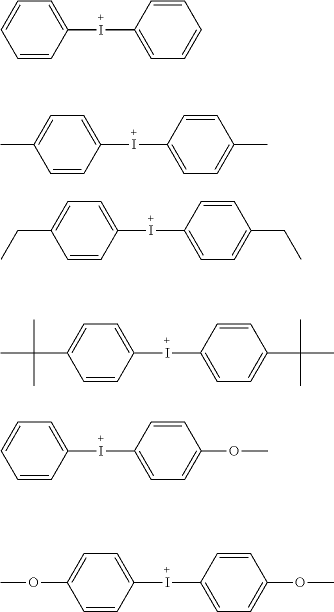

Examples of the cation moiety of formula (Vc) include the moieties as follow.

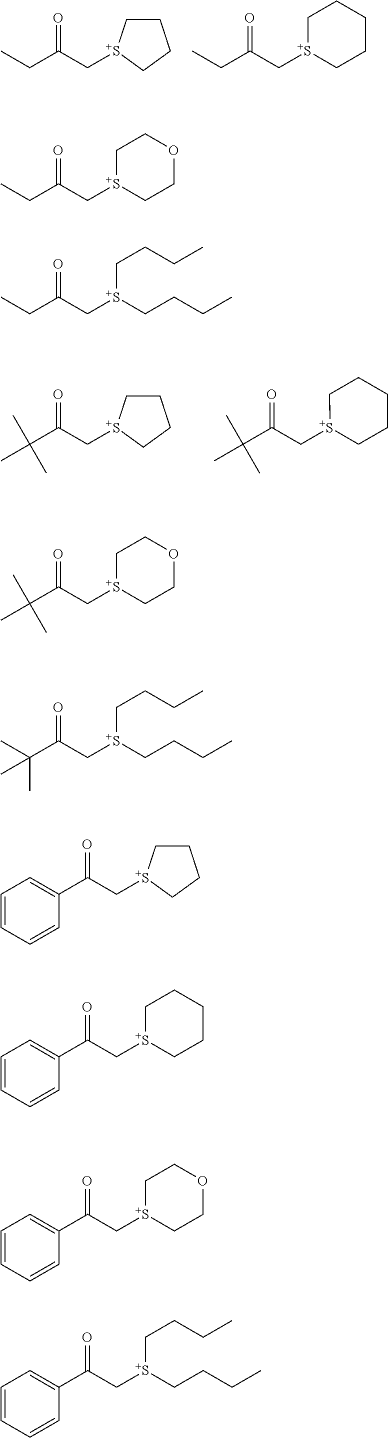

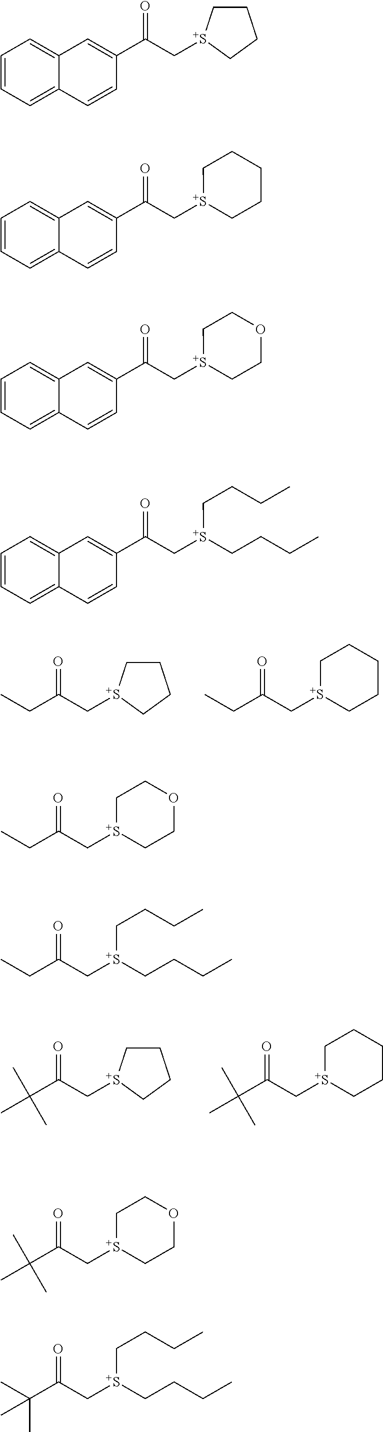

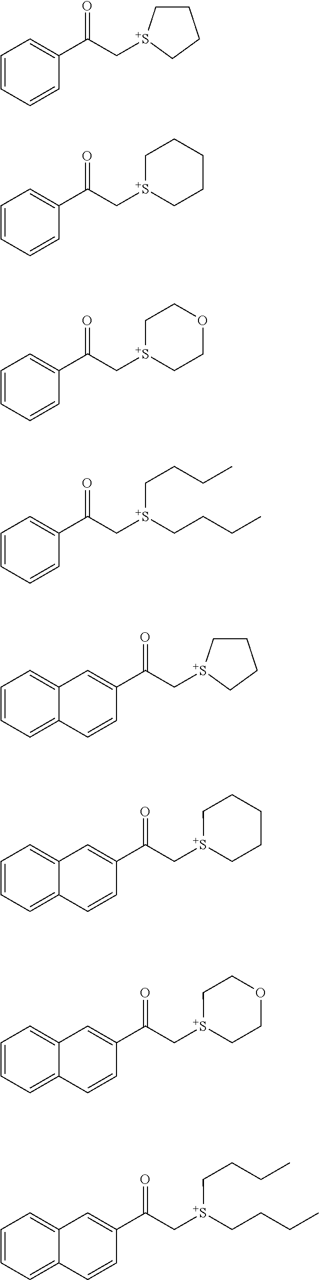

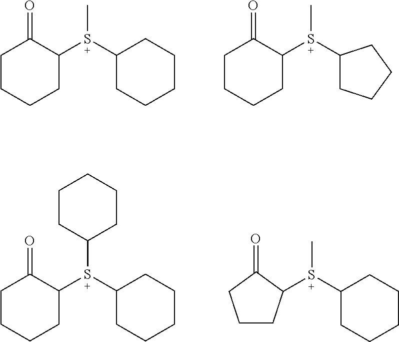

Examples of the cation moiety of formula (III) include the moieties as follow.

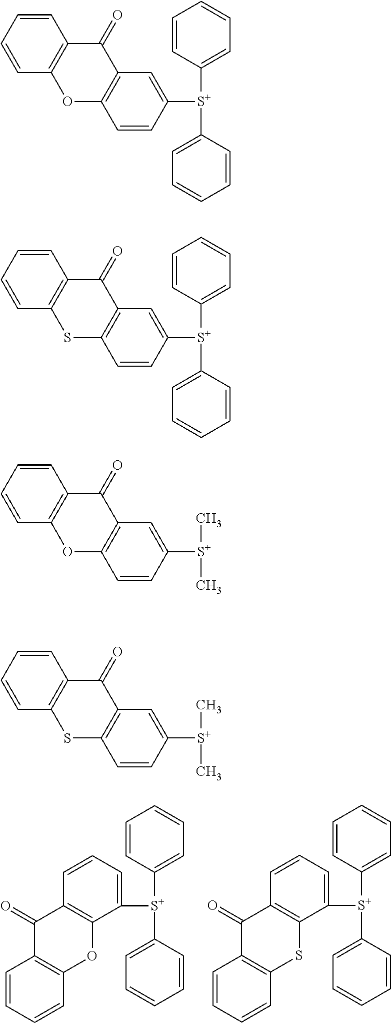 [SMILES: O=c1c2ccccc2oc2ccc([S+](c3ccccc3)c3ccccc3)cc12 ; O=c1c2ccccc2sc2ccc([S+](c3ccccc3)c3ccccc3)cc12 ; C[S+](C)c1ccc2oc3ccccc3c(=O)c2c1 ; C[S+](C)c1ccc2sc3ccccc3c(=O)c2c1 ; O=c1c2ccccc2oc2c([S+](c3ccccc3)c3ccccc3)cccc12 ; O=c1c2ccccc2sc2c([S+](c3ccccc3)c3ccccc3)cccc12]

Examples of the organic anion represented by Z⁻ of formulae (Va), (Vb), (Vc) and (III) include an anion of formula (VII).

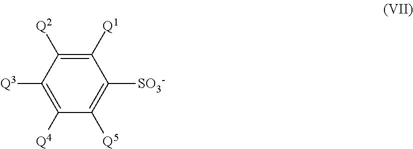

where Q¹, Q², Q³, Q⁴ and Q⁵ independently represent a hydrogen atom, a halogen atom, —CHO, a C1-C16 alkyl group, a C1-C16 alkoxy group, a C1-C8 halogenated alkyl group, a C6-C12 aryl group, a C7-C12 aralkyl group, a cyano group, a C1-C4 alkylthio group, a C1-C4 alkylsulfonyl group, a hydroxyl group, a nitro group, or a group of formula (VIII);

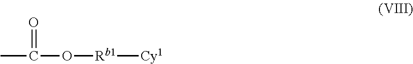

where R^{b1} represents an C1-C16 chain alkanediyl group in which a methylene group may be replaced by an oxygen atom or a sulfur atom, and Cy¹ represents a C3-C20 alicyclic hydrocarbon group. In formula (VII), the alkyl group includes a methyl group, an ethyl group, a propyl group, a butyl group, a pentyl group, a hexyl group, a heptyl group, an octyl group, a decyl group, a dodecyl group, a hexadecyl group, a pentadecyl group, and a hexadecyl group. The alkoxy group includes a methoxy group, an ethoxy group, a propoxy group, a butoxy group, a pentoxy group, a hexyloxy group, a heptyloxy group, an octyloxy group, a decyloxy group, a dodecyloxy group, a hexadecyloxy group, a pentadecyloxy group, and a hexadecyloxy group. The halogenated alkyl group may have one or more halogen, preferably fluorine atoms, which include a perfluoromethyl group, a perfluoroethyl group, a perfluoropropyl group, a perfluorobutyl group. The aryl group may have substituent, which includes a phenyl group, a tolyl group, a methoxyphenyl group and a naphthyl group. The C7-C12 aralkyl group includes benzylic, chlorobenzylic, and methoxybenzylic. The C1-C4 alkylthio group includes methylthio group, ethylthio group, propylthio group and a butylthio group. The C1-C4alkylsulfonyl group includes a methylsulfonyl group, an ethylsulfonyl group, propylsulfonyl group and a butylsulfonyl.
The C1-C16 chain alkanediyl group represented by R^{b1} includes a methylene group, an ethylene group, a propylene group, a butylene group, a pentylene group and a hexylene group. The C1-C16 chain alkanediyl group in which a methylene group has been replaced by an oxygen atom or a sulfur atom include C1-C15 alkyleneoxy groups, C2-C14 alkyleneoxyaklylene groups, C1-C15 alkylenethio groups and C2-C14 alkylenethioaklylene groups. R^{b1} specifically includes the groups of formulae (a-1) to (a-15).

—CH₂— (a-1)

—CH₂—CH₂— (a-2)

—CH₂—CH₂.CH₂— (a-3)

—CH₂—CH₂.CH₂—CH₂— (a-4)

—CH₂—CH₂.CH₂—CH₂.CH₂— (a-5)

—CH₂—CH₂.CH₂—CH₂.CH₂—CH₂— (a-6)

—CH₂—CH₂.CH₂—CH₂.CH₂—CH₂—CH₂—CH₂— (a-7)

—CH₂—O— (a-8)

—CH₂—O—CH₂— (a-9)

—CH₂—O—CH₂—CH₂— (a-10)

—CH₂—CH₂.O—CH₂—CH₂— (a-11)

—CH₂—S— (a-12)

—CH₂—S—CH₂— (a-13)

—CH₂—S—CH₂—CH₂— (a-14)

—CH₂—CH₂.S—CH₂—CH₂— (a-15)

The C3-C20 alicyclic hydrocarbon group represented by Cy¹ includes C3-C20 cycloalkyl group such as a cyclopropyl group, a cyclobutyl group, a cyclopentyl group, a cyclohexyl group, a cycloheptyl group, a cyclooctyl group and, a cyclododecyl group and polycyclic groups e.g. adamantyl group or norbornyl group, which specifically includes the groups of formulae (b-1) to (b-26).

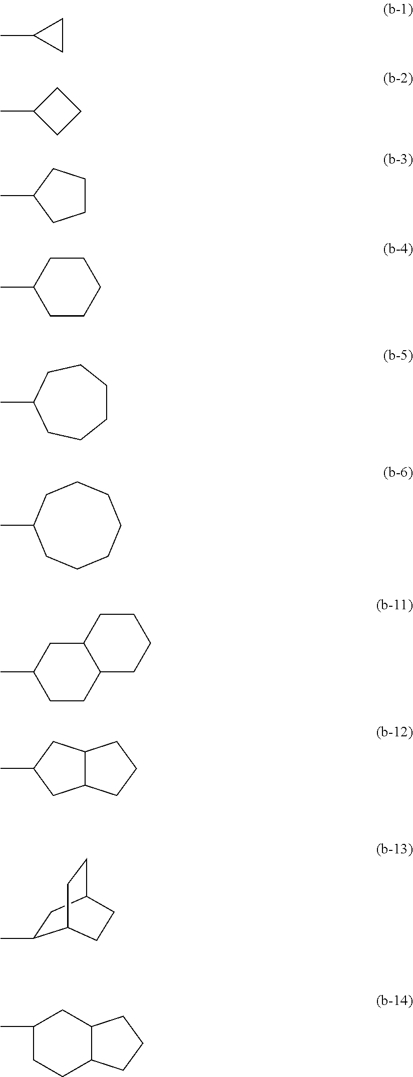

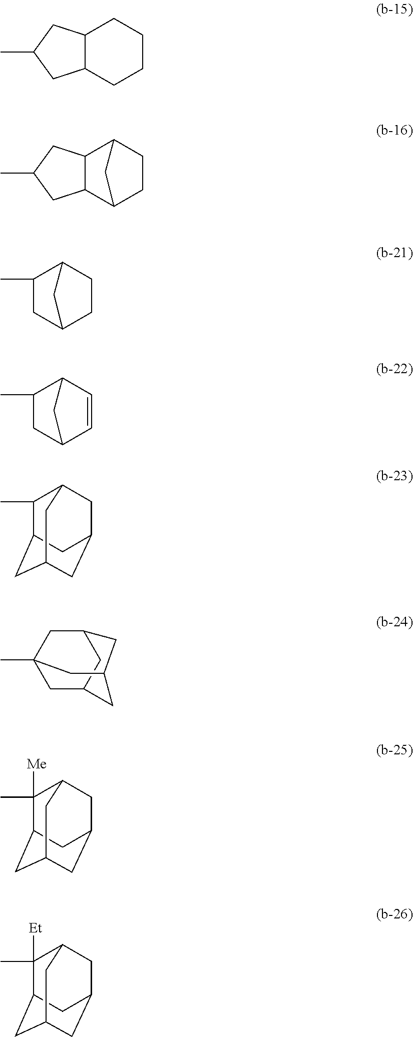

Cy¹ preferably represents cyclohexyl group, norbornyl group, an adamantyl group such as one of formula (b-23) or (b-24). The sulfonate anions of formula (VII) specifically include the anions as follow.

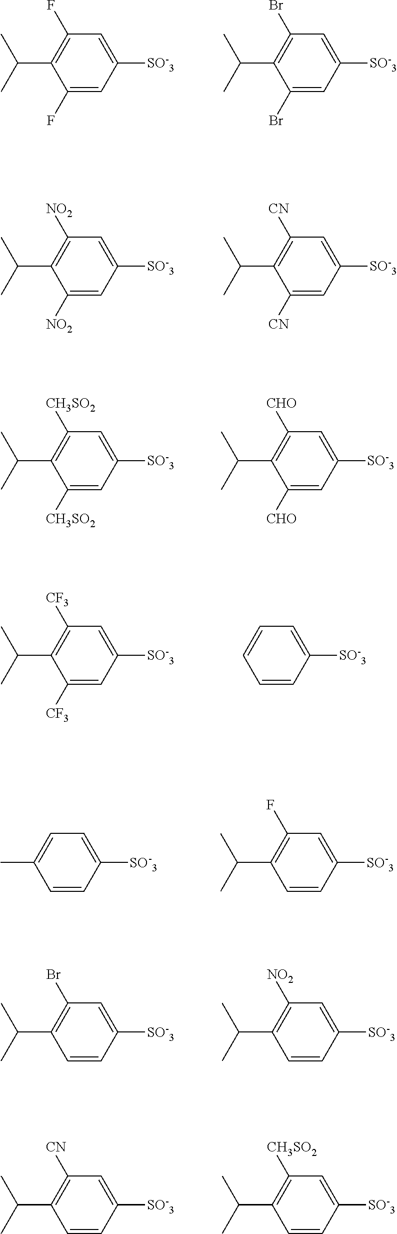

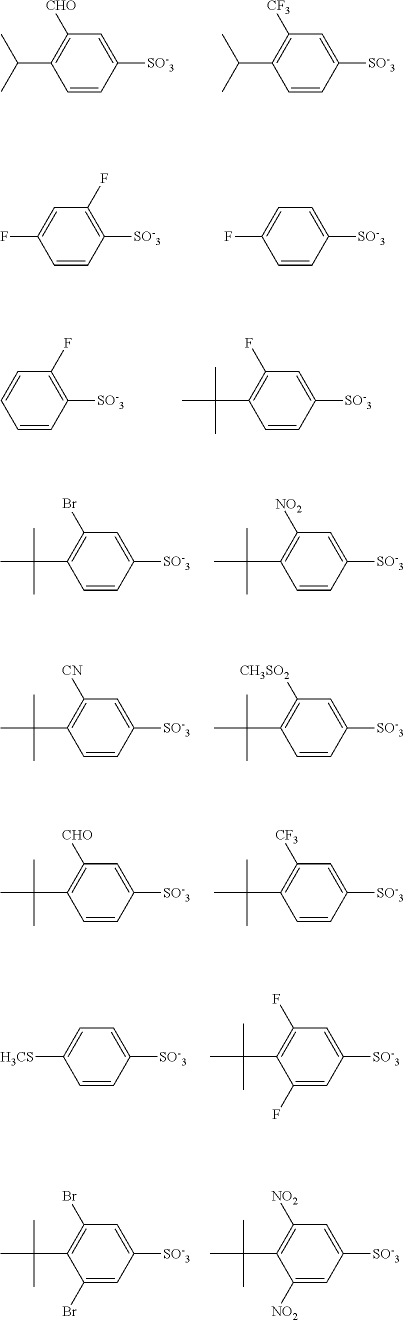

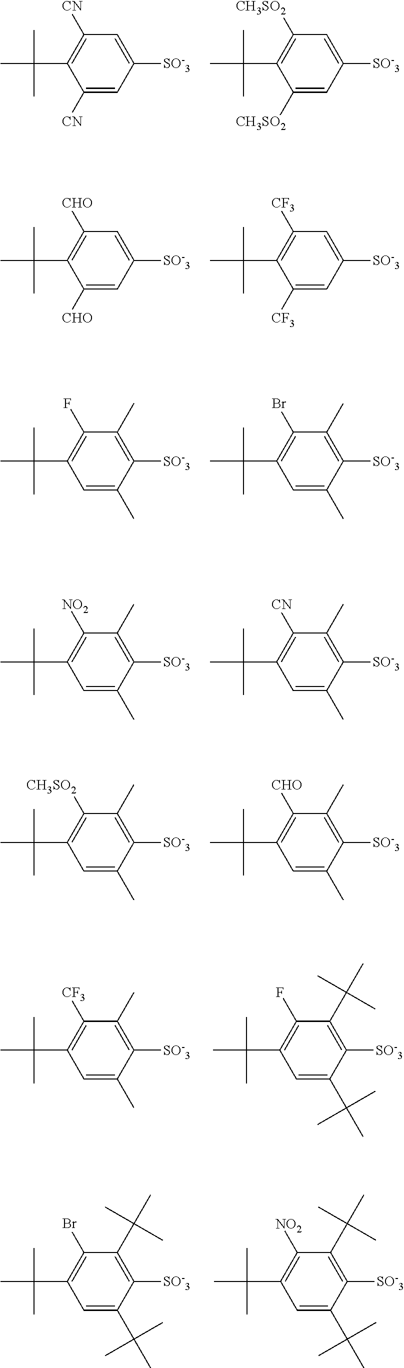

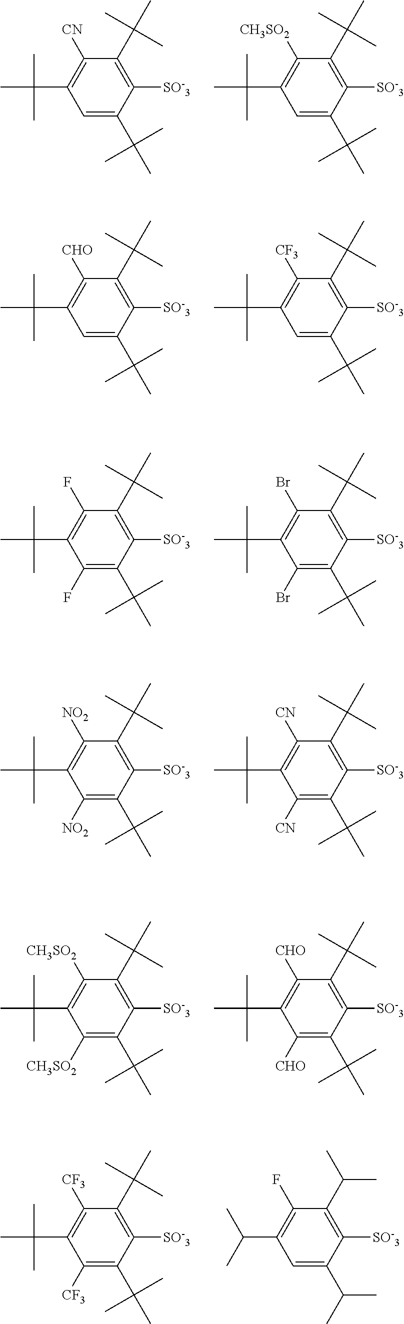

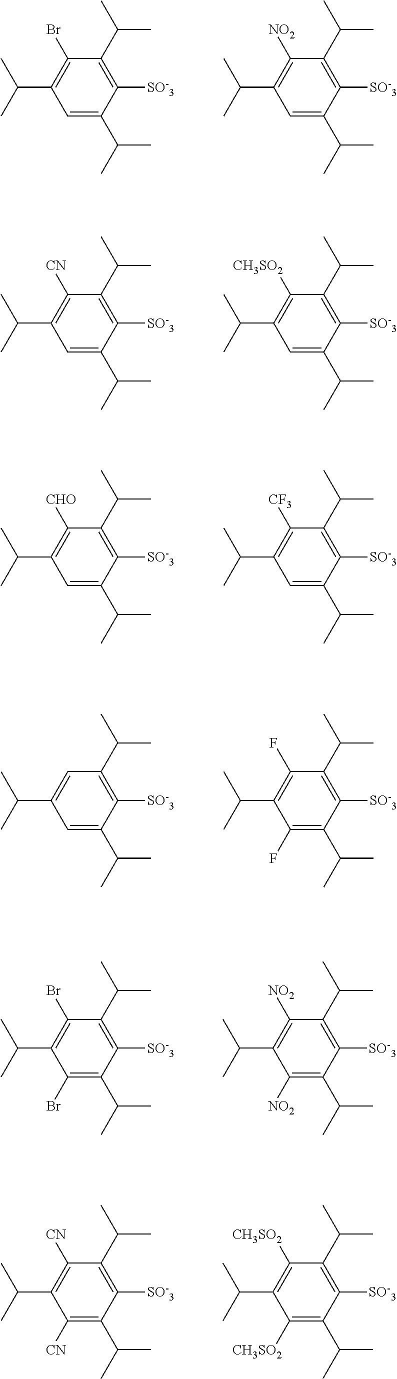

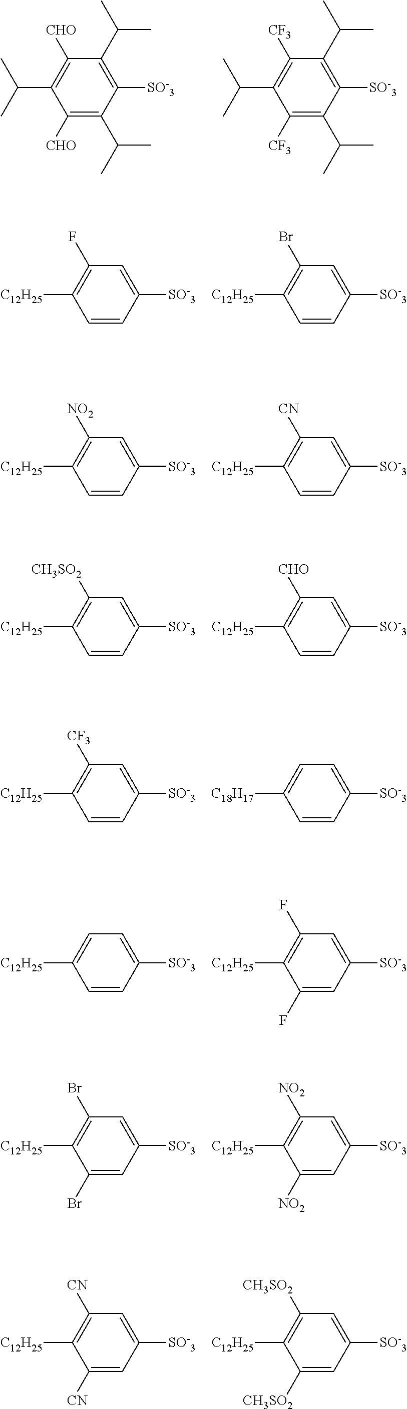

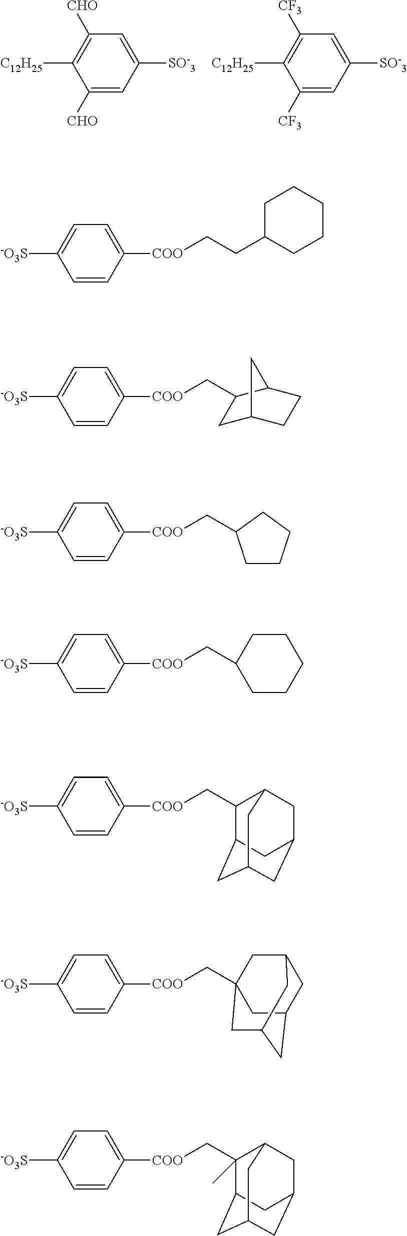

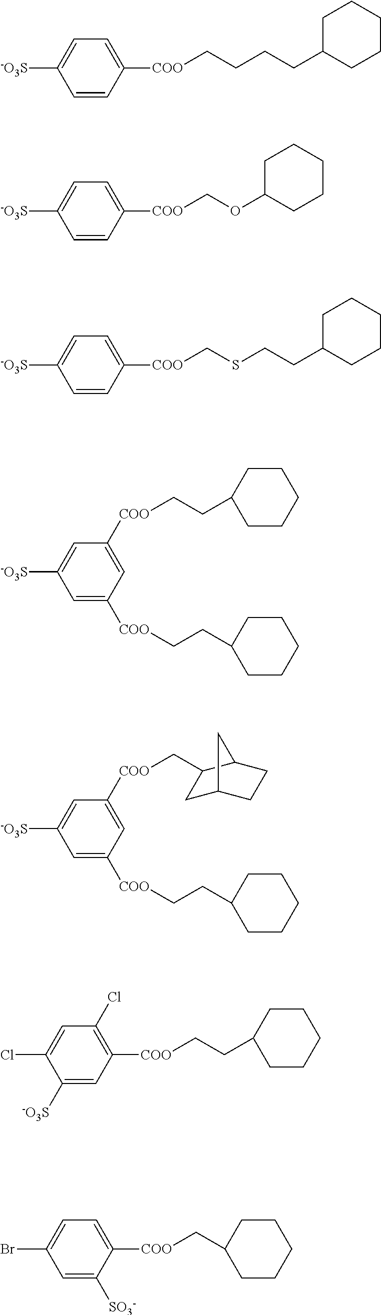

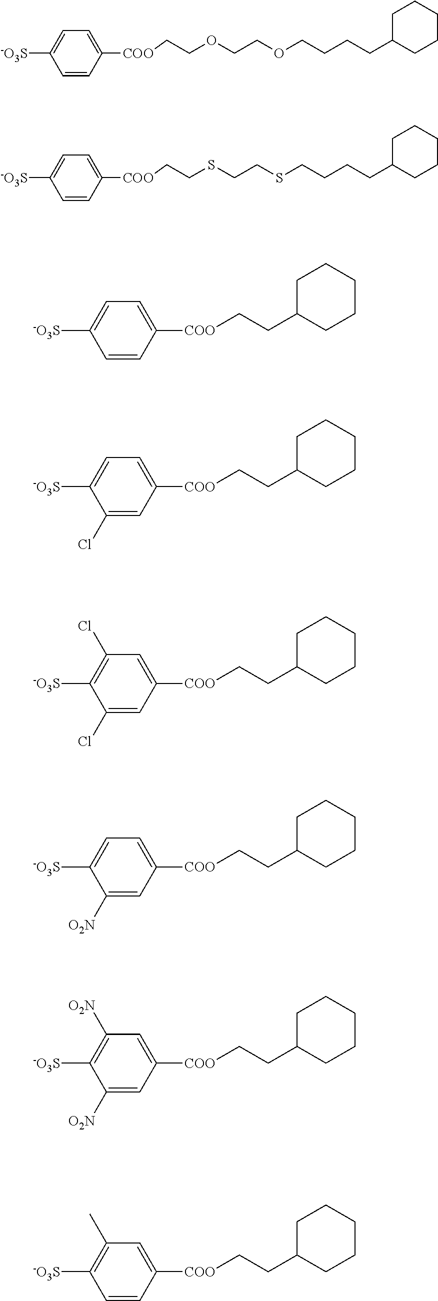

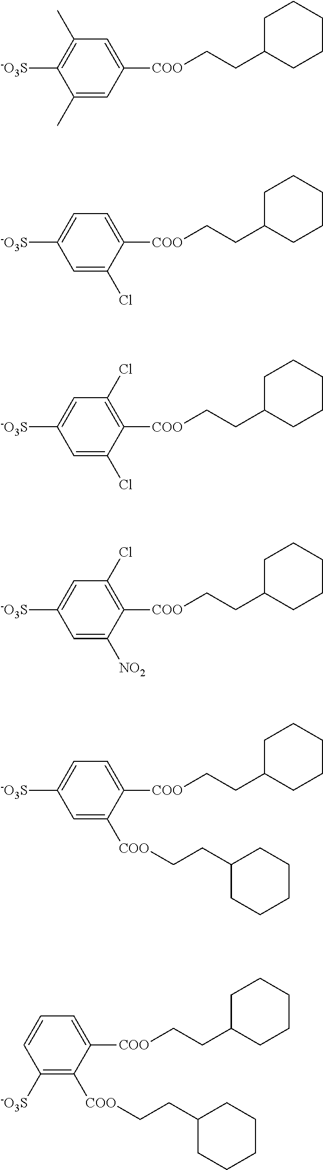

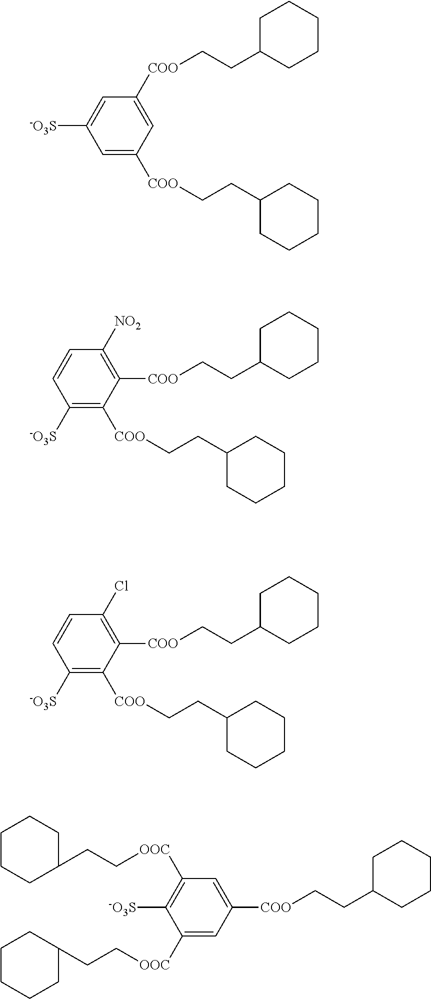

Examples of the organic anion represented by Z⁻ of formulae (Va), (Vb), (Vc) and (III) include that of formula (VIIIa);

^{⊖}SO₃-Q⁶ (VIIIa)

where Q⁶ represents a C1-C20 perfluoroalkyl group, a naphtyl group optionally having a substituent, or an anthryl optionally having a substituent.
In formula (VIIIa), the perfluoroalkyl group includes the perfluoroalkyl group such as a trifluoromethyl group, a pentafluoroethyl group, a heptafluoropropyl group, a nonafluorobutyl group, an undecafluoropentyl group, a tridecafluorohexyl group, and a perfluorododecyl group. The substituent which the naphtyl group or the anthryl has includes C1-C4 alkyl group and C1-C4 alkoxy group.
Examples of the anion of formula (VIIIa) specifically include those as follow.

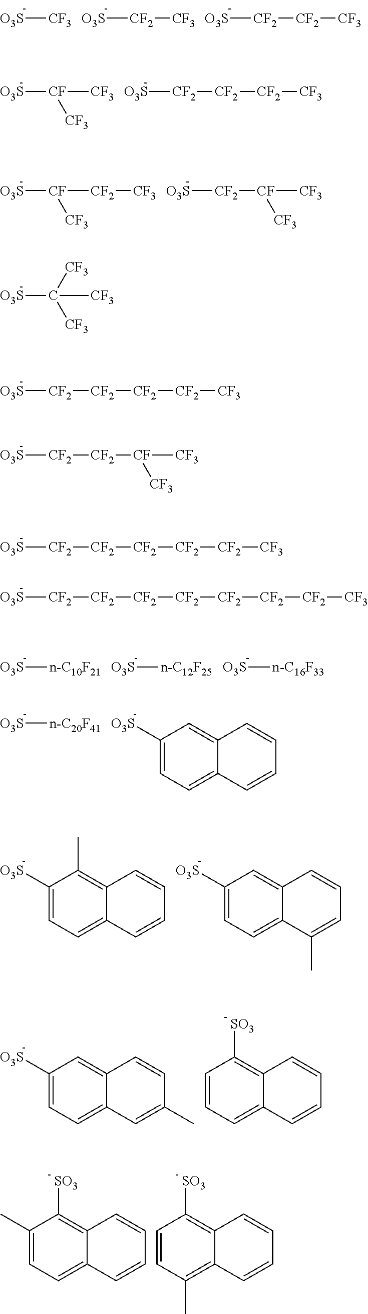

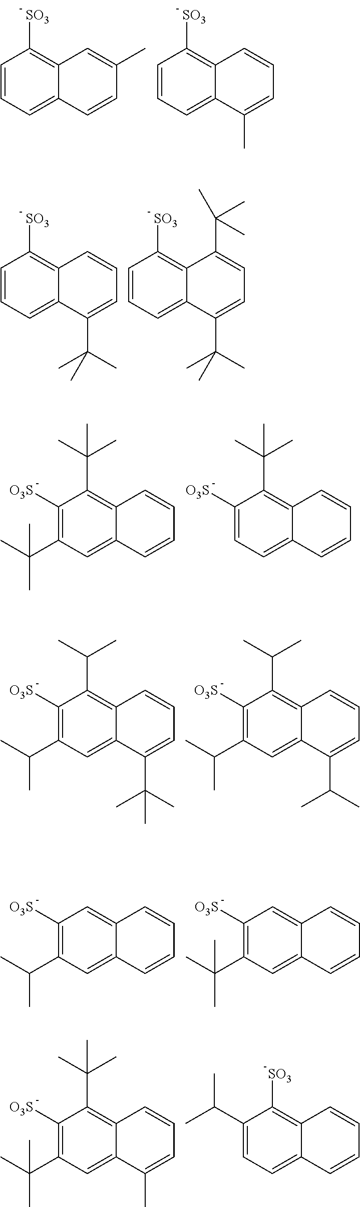

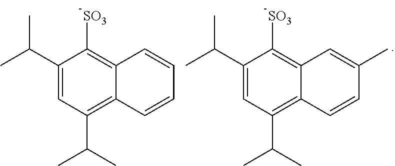

Examples of the organic anion represented by Z⁻ of formulae (Va), (Vb), (Vc) and (III) include the anion of formula (VIIIb);

Q⁷-SO₂—^{⊖}N—SO₂-Q⁸ (VIIIb)

where Q⁷ and Q⁸ represent a C1-C20 perfluoroalkyl group, or a C6-C20 aryl group optionally having a C1-C4 alkyl group. In formula (VIIIb), the perfluoroalkyl group includes a trifluoromethyl group, a pentafluoroethyl group, a heptafluoropropyl group, a nonafluorobutyl group, an undecafluoropentyl group, a tridecafluorohexyl group and a perfluorododecyl group, and the aryl group includes a phenyl group or a naphthyl group.
Examples of the anion of formula (VIIIb) specifically include the anions as follow.

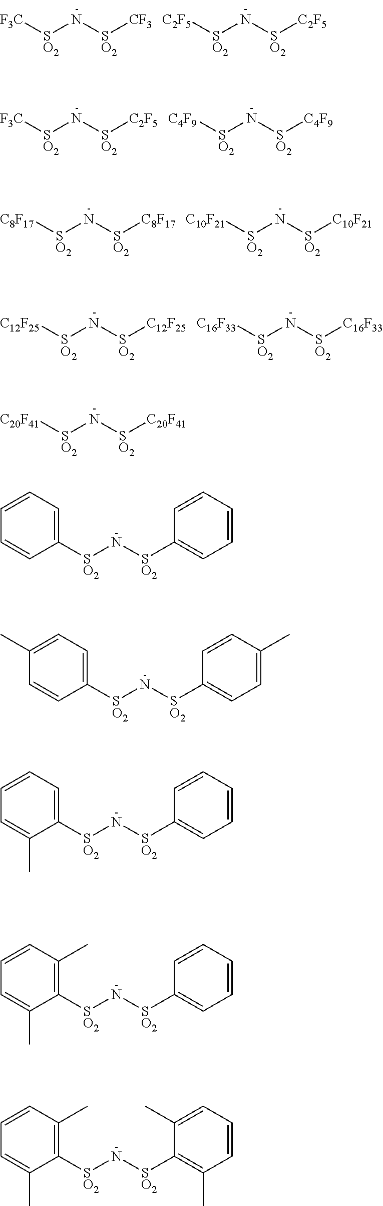

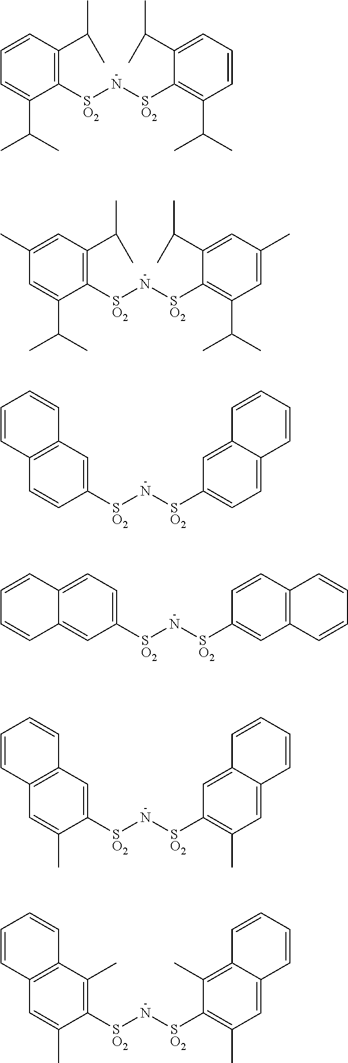

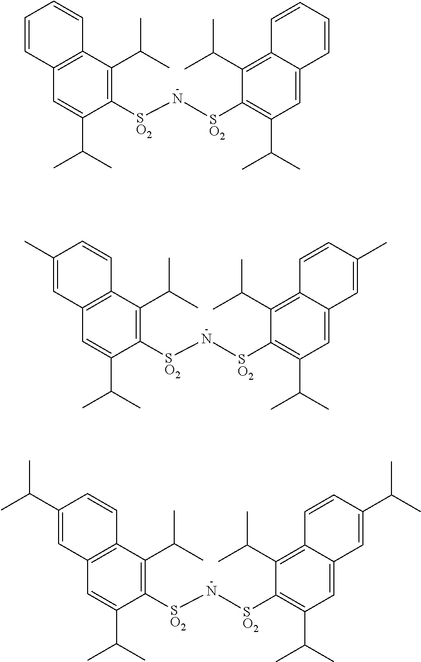

The acid generator for the present invention includes the compounds which comprise any one of the cations as specifically described and any one of the anions as specifically described.
Examples of the non-ionic acid generators include an organic sulfone compound such as the compounds of formulae (IV), (VI), (IX), (XI) and (XII);

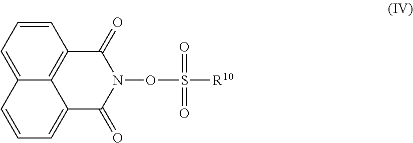

where R¹⁰ represents a C1-C8 perfluoroalkyl group, a C6-C16 aromatic hydrocarbon group optionally having a substituent, a C1-C12 alkyl group optionally having a substituent, or a C3-C16 cycloalkyl group optionally having a substituent,

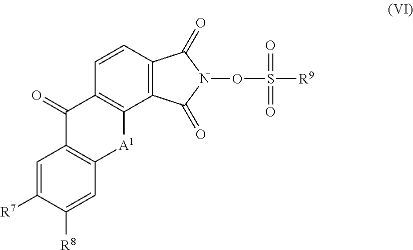

where A¹ represents an oxygen atom or a sulfur atom,
R⁷ and R⁹ represent a hydrogen atom, or a C1-C4 alkyl group, and R⁹ represents a C1-C8 perfluoroalkyl group,

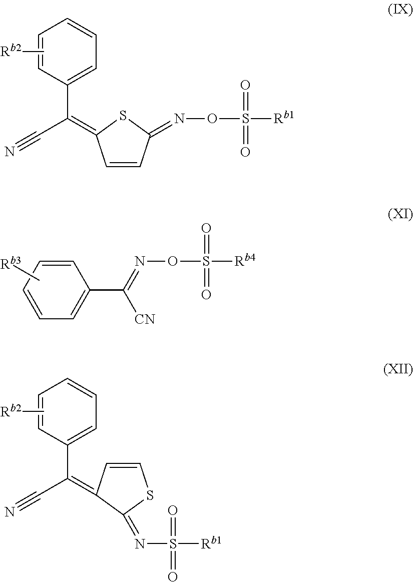

where R^{b1} and R^{b4} each represents a C1-C18 hydrocarbon group optionally having a fluorine atom, and
R^{b2} and R^{b4} each represent a hydrogen atom and a C1-C5 alkyl group or a C1-C5 alkoxy group.
In formula (IV), examples of the C1-C8 perfluoroalkyl group are the same as those for formula (III). Examples of C1-C12 alkyl group include a methyl group, an ethyl group, a propyl group, a butyl group, a pentyl group, a hexyl group, a heptyl group, an octyl group, a decyl group, and a dodecyl group. Examples of C3-C16 cycloalkyl group include monocyclic groups such as a cyclopropyl group, a cyclobutyl group, a cyclopentyl group, a cyclohexyl group, a cycloheptyl group, a cyclooctyl group and, a cyclododecyl group. Examples of the substituent for the alkyl group and the cycloalkyl group include a halogen atom such as a fluorine atom or a chlorine atom; and a lactone ring.
Examples of the aromatic hydrocarbon group include a phenyl group and a naphthyl group. Examples of the substituent for the aromatic group include C1-C4 alkyl group and a halogen atom such as a fluorine atom or a chlorine atom.
In formula (VI), examples of the C1-C8 perfluoroalkyl group are the same as those for formula (III) and C1-C4 alkyl group are the same as those for formula (Vc).

The hydrocarbon group of formula (IX) includes a C1-C18 alkyl group such as a methyl group, an ethyl group, a propyl group, a butyl group, a pentyl group, a hexyl group, a heptyl group, an octyl group, a decyl group, and a dodecyl group;

a C3-C18 cycloalkyl group such as a cyclopropyl group, a cyclobutyl group, a cyclopentyl group, a cyclohexyl group, a cycloheptyl group, a cyclooctyl group, a cyclodecyl group, a cyclododecyl group and an adamantyl group; and a C6-C18 aryl group such as a phenyl group, a naphthyl group, an anthryl group, biphenyl group, phenanthryl group, fluorenyl group.

Examples of the compound represented by formula (IV) specifically include the compound as follow, preferably include the compounds of the formula where R¹⁰ is C1-C4 perfluoroalkyl group.

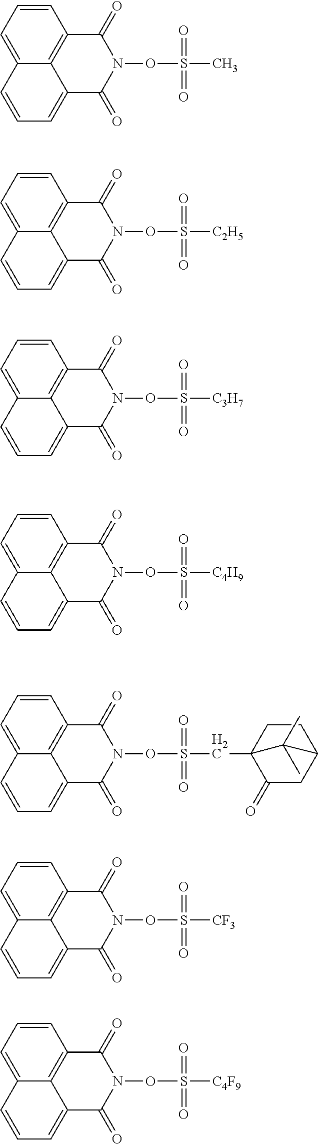

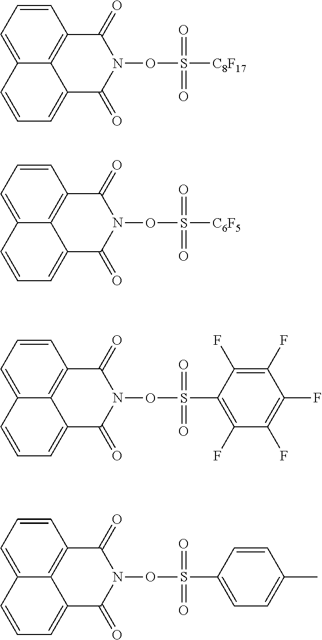

Examples of the compound represented by formula (VI) specifically include the compounds as follow.

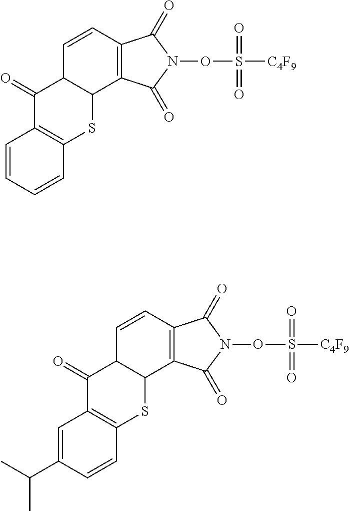

Examples of the compound represented by formula (IX) specifically include the compounds as follow.

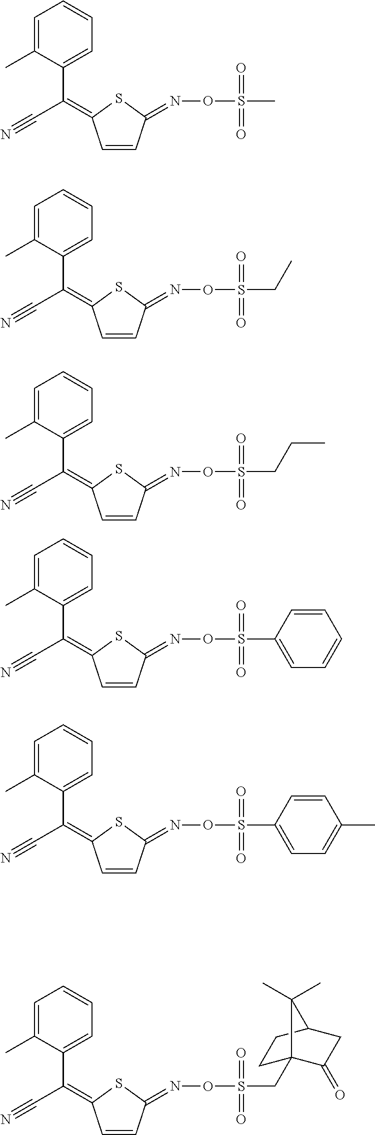

Examples of the compound represented by formula (XI) specifically include the compounds as follow.

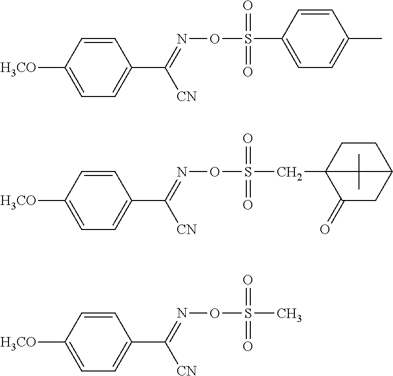 [SMILES: COc1ccc(/C(C#N)=N/OS(=O)(=O)c2ccc(C)cc2)cc1 ; COc1ccc(/C(C#N)=N/OS(=O)(=O)CC23CCC(CC2=O)C3(C)C)cc1 ; COc1ccc(/C(C#N)=N/OS(C)(=O)=O)cc1]

Examples of the compound represented by formula (XII) specifically include the compounds as follow.

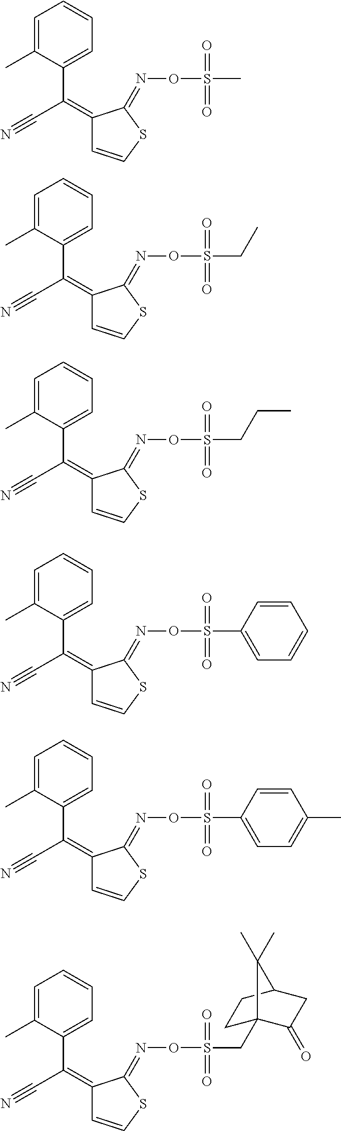

The acid generator for the present invention is preferably an organic sulfone compound, more preferably a compound represented by formula (IV) or (VI), still more preferably a compound represented by formula (IV).
The acid generator is available on the market, or it can be prepared by a known method.
The content of the acid generator is preferably 0.05 to 5% by weight, more preferably 0.1 to 1% by weight, of the total amount of the composition of the present invention.
The composition of the present invention comprises the compound represented by formula (X1) (Hereinafter, the compound represented by formula (X1) is referred to as “Compound (X1)”).

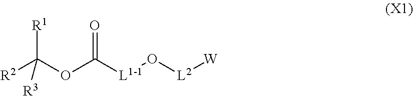

In formula (X1), R¹, R² and R³ each independently represent a hydrogen atom, a C1-C12 alkyl group, a C3-C12 alicyclic hydrocarbon group, a C6-C30 aryl group, or a C7-C31 aralkyl group, or two of R¹, R² and R³ are bonded to each other to represent a C2-C10 divalent aliphatic hydrocarbon group,
L¹⁻¹ represents a group represented by formula (X1-1):

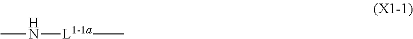

or a group represented by formula (X1-2):

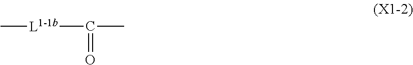

L² represents a single bond, or a C1-C12 saturated aliphatic hydrocarbon group, and
W represents a C6-C30 aromatic hydrocarbon group which optionally has a substituent.
The alkyl groups represented by R¹, R² and R³ include a methyl group, an ethyl group, a propyl group, a butyl group, a pentyl group, a hexyl group, a heptyl group, an octyl group, a decyl group, and a dodecyl group, preferably C1-C5 alkyl group, more preferably a methyl group and an ethyl group.

The alicyclic hydrocarbon groups represented by R¹, R² and R³ include monocyclic hydrocarbon groups such as a cyclopropyl group, a cyclobutyl group, a cyclopentyl group, a cyclohexyl group, a cycloheptyl group, a cyclooctyl group and, a cyclododecyl group, e.g. the groups represented by formulae (KA-1), (KA-2), (KA-3), (KA-4), (KA-5), (KA-6) and (KA-7), and polycyclic hydrocarbon groups, e.g. the groups represented by formulae (KA-8), (KA-9), (KA-10), (KA-11), (KA-12) and (KA-13), preferably C3-C7 cycloalkyl group, more preferably cyclohexyl group.

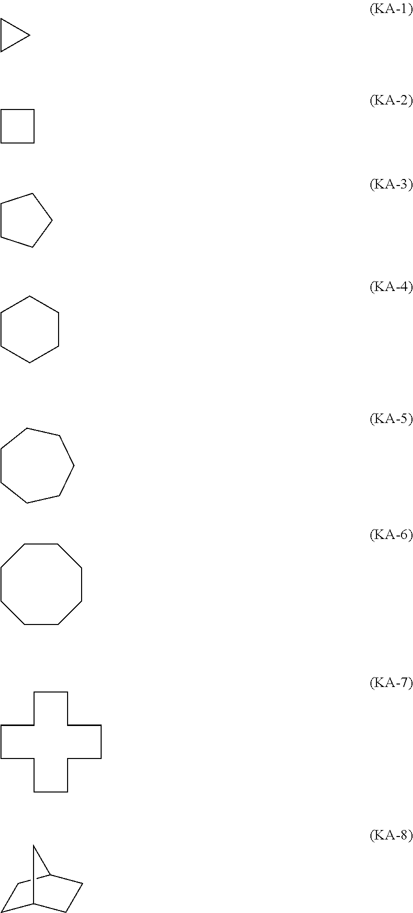

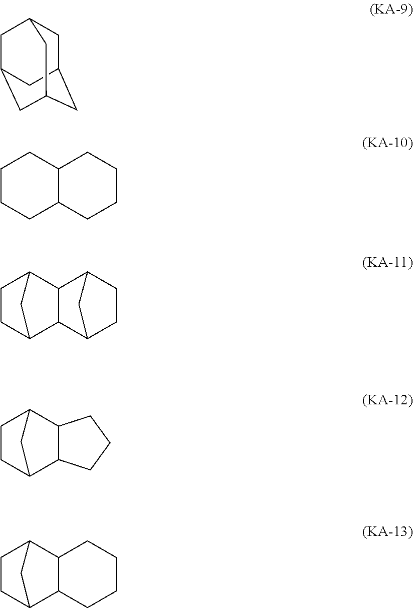

The aryl groups represented by R¹, R² and R³ include a phenyl group, a naphthyl group, a biphenyl group, an anthryl group, a phenanthryl group, preferably C6-C12 aryl group, more preferably phenyl group.
The aralkyl groups represented by R¹, R² and R³ include a benzyl group, a phenethyl group, phenylpropyl group and a naphtylmethyl group, preferably C7-C13 aralkyl group, more preferably benzyl group.
Two of R¹, R² and R³ may be bonded to each other to represent a C2-C10 divalent aliphatic hydrocarbon group such as the groups shown below.

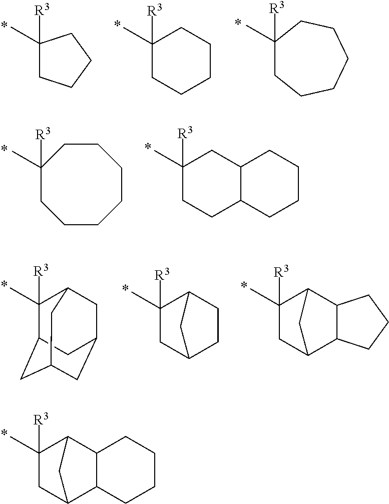

The moiety —C(R¹) (R²) (R³) preferably represents tert-butyl group or tert-pentyl group.
L¹⁻¹ represents a group represented by formula (X1-1) or a group represented by formula (X1-2).
In formula (X1-1), L^{1-1a} represents a single bond, or a C1-C30 hydrocarbon group.
The hydrocarbon group represented by L^{1-1a} includes a C1-C30 saturated aliphatic hydrocarbon group, a C6-C30 aryl group, and a C7-C30 aralkyl group.
The saturated aliphatic hydrocarbon group includes a C1-C30 alkyl group such as a methyl group, an ethyl group, a propyl group, a butyl group, a pentyl group, a hexyl group, a heptyl group, an octyl group, a decyl group, and a dodecyl group; a C3-C30 alicyclic hydrocarbon group such as a cyclopropyl group, a cyclobutyl group, a cyclopentyl group, a cyclohexyl group, a cycloheptyl group, a cyclooctyl group a cyclododecyl group, and the groups represented by formulae (KA1) to (KA13); and combinations of those alkyl and alicyclic hydrocarbon groups.
The alicyclic hydrocarbon group may comprise two carbon atoms, which is attached to each other, one of which is also attached to the nitrogen atom of —NH— in formula (X1-1) and the other of which is attached to the oxygen atom of —O-L²- in formula (X1).
The hydrocarbon group represented by L^{1-1a} is preferably C2-30 branched hydrocarbon group, more preferably a C2-12 branched hydrocarbon group, such as a hydrocarbon group having C1-C12 alkyl group or C7-C12 aralkyl group as a branched chain, still more preferably a hydrocarbon group having C1-C7 alkyl group or a benzyl group as a branched chain, because the photoresist composition which comprises Compound (X1) where L^{1-1a} is a branched aliphatic hydrocarbon group can provide a photoresist pattern with high resolution.
Examples of the aryl group represented by L^{1-1a} include those as mentioned above as to R¹, R² and R³. The aryl group represented by L^{1-1a} may comprise two carbon atoms, attached to each other, one of which is attached to the nitrogen atom of —NH— in formula (X1-1) and the other of which is attached to the oxygen atom of —O-L²- in formula (X1).
Examples of the aralkyl group represented by L^{1-1a} are the same as mentioned above as to R¹, R² and R³.
The hydrocarbon group represented by L^{1-1a} optionally has a substituent selected from a hydroxyl group, an amino group or a mercapto group.
A methylene group of the hydrocarbon group represented by L^{1-1a} is optionally replaced by an oxygen atom, an imino group, a sulfur atom or a carbonyl group.
The hydrocarbon group represented by L^{1-1a} preferably has a carbonyl group attaching to the oxygen atom of the moiety —O-L²-.
The heterocyclic ring represented by L^{1-1b} has one nitrogen atom bonded to —C(═O)— of the moiety —C(═O)-L¹⁻¹- in formula (X1) and
one carbon atom attached to the nitrogen atom and to the carbon atom of the carbonyl group of formula (X1-2).
The heterocyclic ring represented by L^{1-1b} generally has one nitrogen atom, which is preferably constituted by one nitrogen atom and two to nine methylene groups.
Examples of the heterocyclic ring represented by L^{1-1b} include the groups represented as follow:

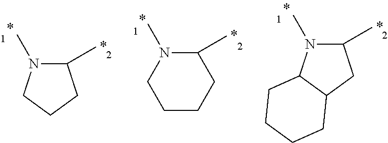

where 1* represents a binding position to —C(═O)— of the moiety —C(═O)-L¹⁻¹- in formula (X1), and 2* represents a binding position to the carbon atom of the carbonyl group of formula (X1-2).
L² represents a single bond, or a C1-C12 saturated aliphatic hydrocarbon group.
The saturated aliphatic hydrocarbon group represented by L² includes a C1-C12 alkyl group such as a methyl group, an ethyl group, a propyl group, a butyl group, a pentyl group, a hexyl group, a heptyl group, an octyl group, a decyl group, and a dodecyl group; and a C3-C12 cycloalkyl group such as a cyclopropyl group, a cyclobutyl group, a cyclopentyl group, a cyclohexyl group, a cycloheptyl group, a cyclooctyl group a cyclododecyl group, and the groups represented by formulae (KA1) to (KA10).
The saturated aliphatic hydrocarbon group represented by L² has preferably 1 to 6 carbon atoms. L² is preferably a single bond and a methylene group.
W represents a C6-C30, preferably C6-C12, aromatic hydrocarbon group which optionally has a substituent.
The substituent in the aromatic hydrocarbon group represented by W includes a halogen atom, a nitro group, an amino group, a hydroxyl group, a mercapto group, a carbamoyl group, a C1-C4 alkyl group such as methyl group, and a C1-C4 alkoxy group, preferably a nitro group.
W is preferably a group represented by formula (X2);

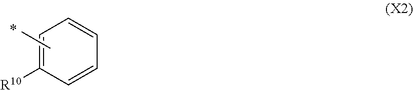

where R¹⁰ represents a hydrogen atom or a nitro group, and
* is a binding position to L².
The group represented by formula (X2) is preferably a group represented by formula (X2-1);

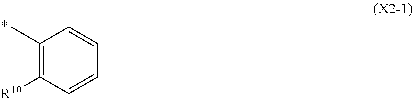

where R¹⁰ and * are as defined above.
In formula (X1), L¹⁻¹ preferably represents a group represented by formula (X1-1). In formula (X1-1), L^{1-1a} preferably represents a single bond, a C6-C10 aromatic hydrocarbon group, a C3-C10 alicylcic hydrocarbon group, or a C1-C30 aliphatic hydrocarbon group in which a methylene group is optionally replaced by an oxygen atom, a sulfur atom or a carbonyl group and in which a hydrogen atom is optionally replaced by a C6-C30 aryl group or a C7-C31 aralkyl group.
The compound represented by formula (X-1) is preferably represented by formula (X) (hereinafter, the compound represented by formula (X) is referred to as “Compound (X)”).

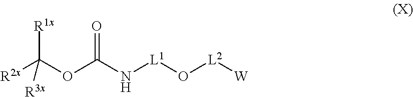

In formula (X), W and L² are as defined above,
R^{1X}, R^{2X} and R^{3X} each independently represent a hydrogen atom, a C1-C12 alkyl group, a C3-C12 alicyclic hydrocarbon group, a C6-C30 aryl group, or a C7-C31 aralkyl group, and L¹ represents a single bond, or a C1-C30 saturated aliphatic hydrocarbon group where a methylene group is optionally replaced by an oxygen atom, a sulfur atom or a carbonyl group and where a hydrogen atom is optionally replaced by a C6-C30 aryl group or a C7-C31 aralkyl group.
Examples of each group represented by R^{1X}, R^{2X} and R^{3X} are the same as mentioned regarding the groups represented by R¹, R² and R³.
Examples of the saturated aliphatic hydrocarbon group represented by L¹ are the same as mentioned as to L¹⁻¹. The saturated aliphatic hydrocarbon group represented by L¹ is preferably a branched aliphatic hydrocarbon group, more preferably C2-C12, still more preferably C2-C7 branched aliphatic hydrocarbon group.
When a methylene group has been replaced by an oxygen atom in the saturated aliphatic hydrocarbon group represented by L¹, examples of Compound (X) include the followings:

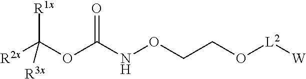

where R^{1X}, R^{2X}, R^{3 X} and L² are the same as defined above. When a methylene group has been replaced by a sulfur atom in the saturated aliphatic hydrocarbon group represented by L¹, examples of Compound (X) include the followings:

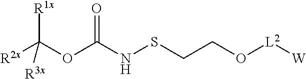

where R^{1X}, R^{2X}, R^{3X} and L² are the same as defined above. When a methylene group has been replaced by a carbonyl atom in the saturated aliphatic hydrocarbon group represented by L¹, examples of Compound (X) include the followings:

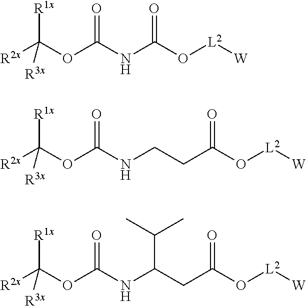

where R^{1X}, R^{2X}, R^{3 X} and L² are the same as defined above. In the saturated aliphatic hydrocarbon group represented by L¹, one or more hydrogen atoms are optionally replaced by a C6-C30 aryl group or C7-C31 aralkyl group, preferably C6-C12 aryl group or C7-C13 aralkyl group. Preferably one hydrogen atom is optionally replaced by C7-C13 aralkyl group such as a benzyl group.
The composition of the present invention is preferably represented by formula (X), in which R^{1X}, R^{2X} and R^{3X} each independently represent a hydrogen atom, or a C1-C3 alkyl group,
L¹ represents a single bond, or a C1-C5 saturated aliphatic hydrocarbon group where a methylene group is optionally replaced by a carbonyl group and where a hydrogen atom is optionally replaced by a C7-C10 aralkyl group,
L² represents a single bond or a methylene group, and
W represents a group of formula (X2)

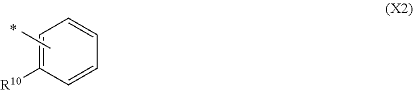

where R¹⁰ represents a hydrogen atom or a nitro group, and
* is a binding position to L².
Preferred examples of L¹ include a single bond and a group represented by formula (X3).

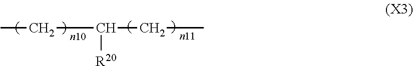

In the formula (X3), n¹⁰ and n¹¹ each independently represent an integer of 0 or more and R²⁰ represents an aryl group or an aralkyl group, provided that the total number of the carbon atoms in formula (X3) is 13 or less.
Specific examples of Compound (X1) include the following ones:

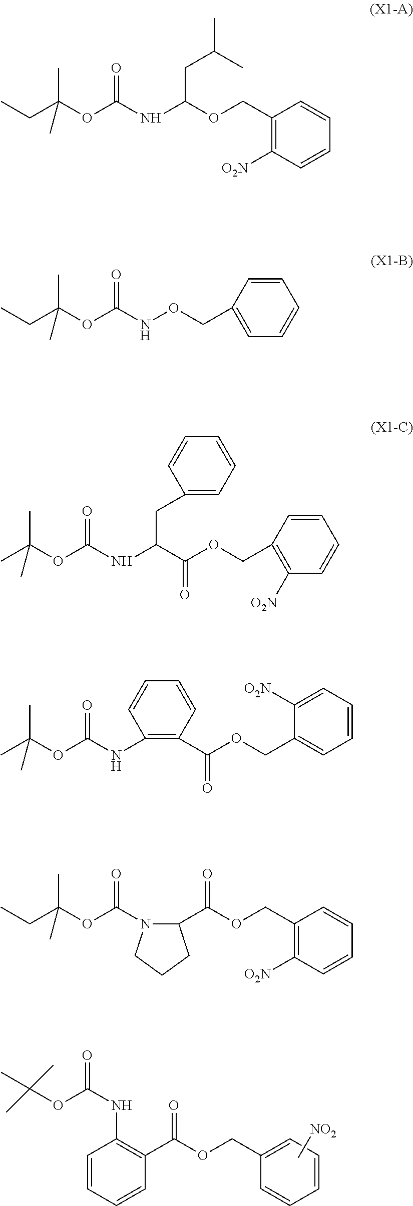

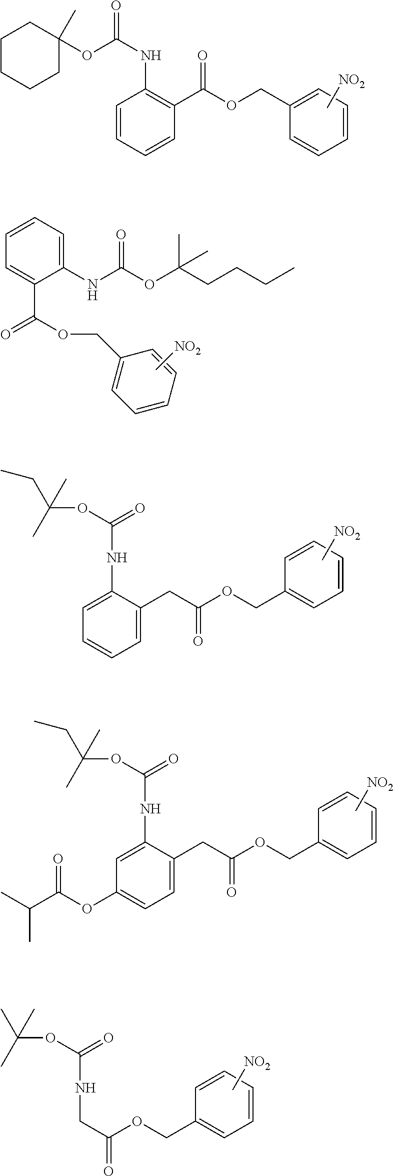

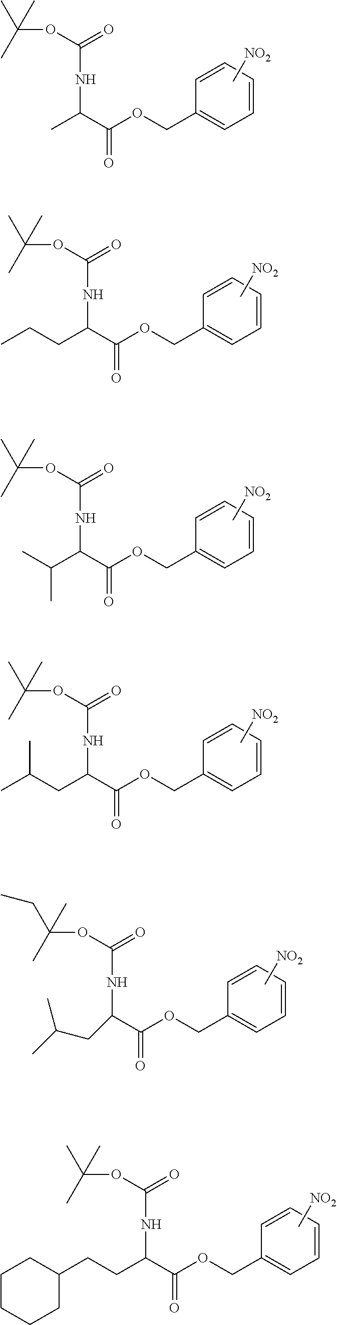

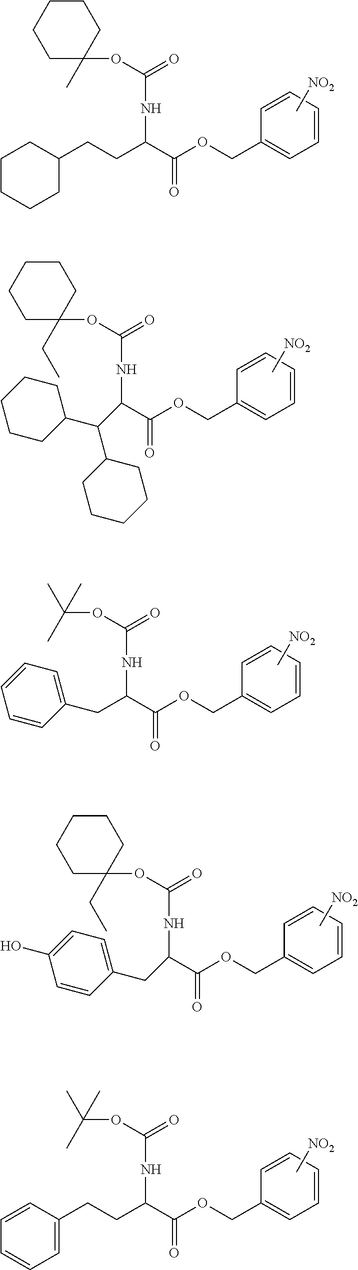

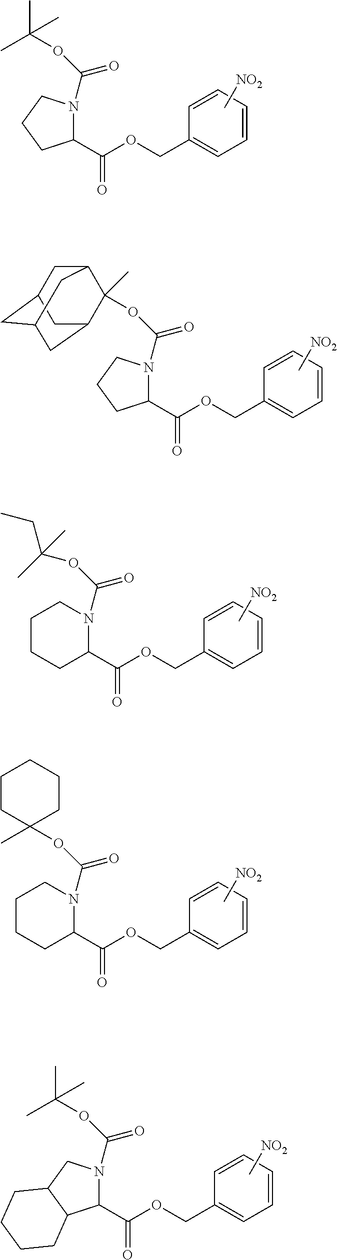

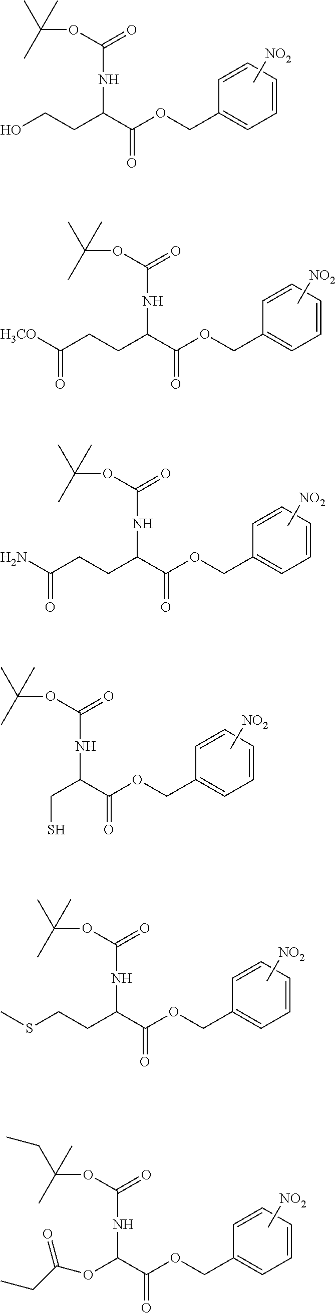

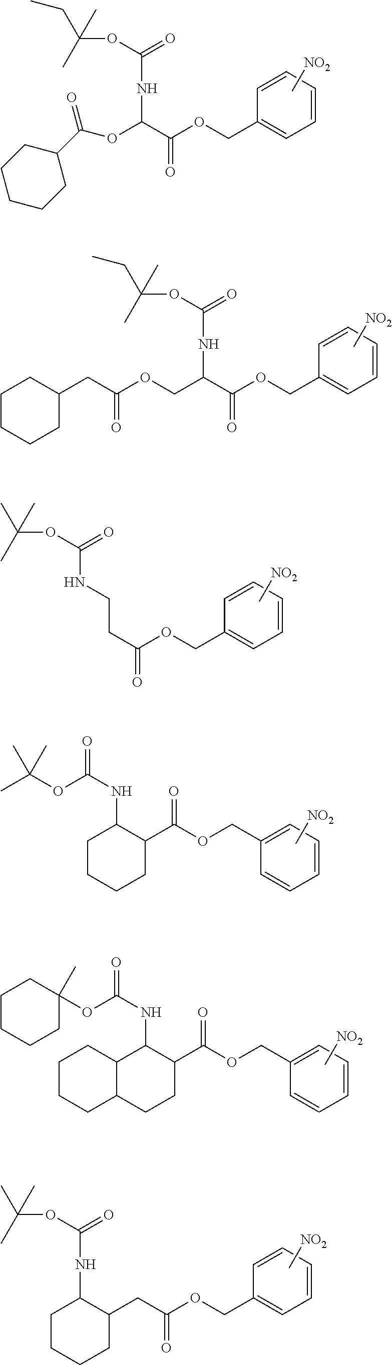

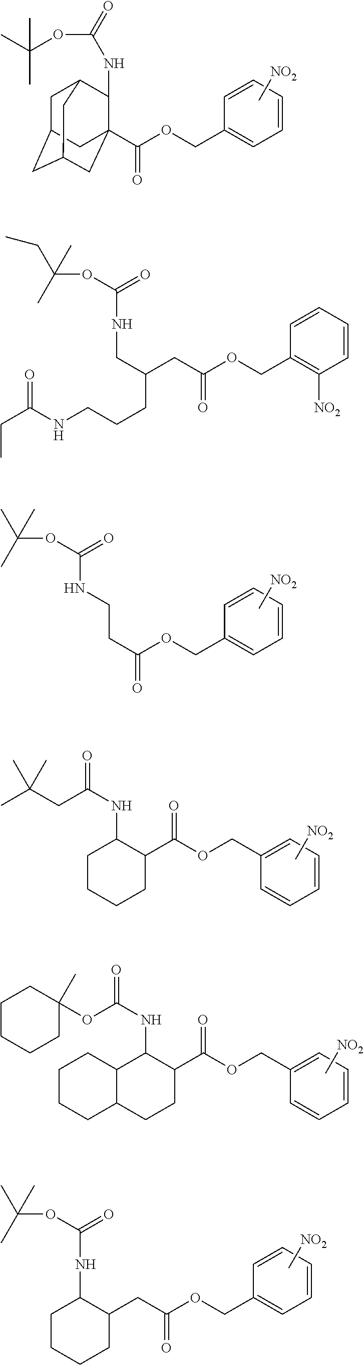

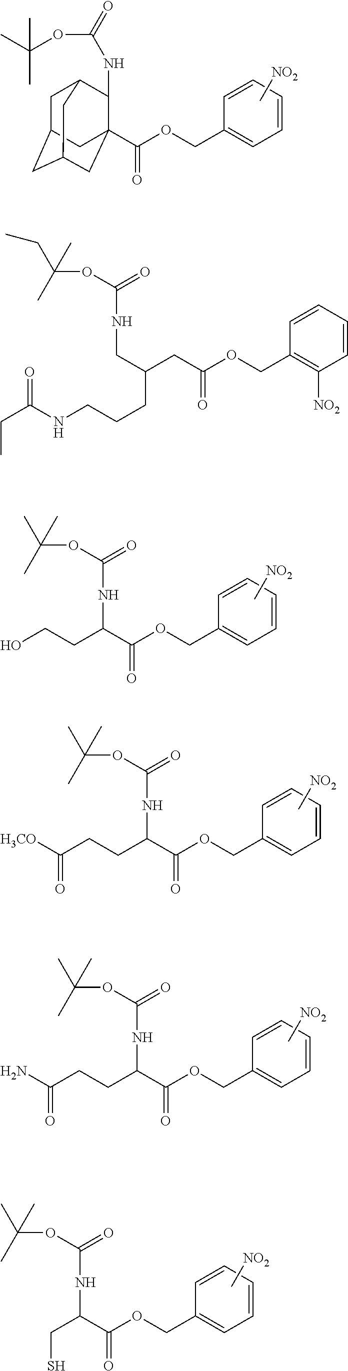

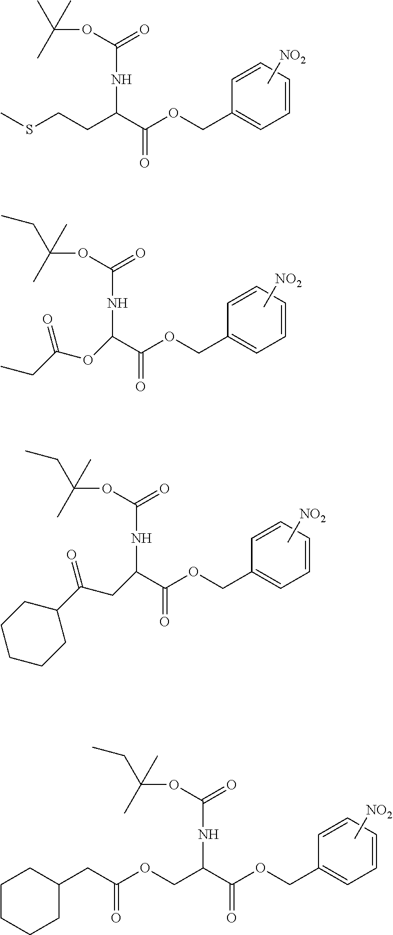

Among them, the compound represented by formulae (X1-A), (X1-B) and (X1-C) are preferred as Compound (X1).
Compound (X1) can be prepared by a known method as mentioned in US2011/039209A1.
The content of the compound represented by formula (X1) is usually 0.005 to 5%, preferably 0.1 to 1% of the total amount of the composition of the present invention.
The composition of the present invention may further comprise a basic compound known as a quencher for the photoresist compositions.
The basic compound includes an amine and an ammonium salt. The amine includes an aliphatic amine and an aromatic amine. The aliphatic amine includes primary amine, secondary amine and tertiary amine.
The basic compound specifically includes the compounds of formulae (C1), (C2), (C3), (C4), (C5) and (C6), preferably a compound represented by formula (C1-1).

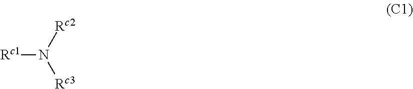

wherein R^{c1}, R^{c2} and R^{c3} independently represent a hydrogen atom, a C1-C6 alkyl group, a C5-C10 alicyclic hydrocarbon group or a C6-C10 aromatic hydrocarbon group, and the alkyl group and the alicyclic hydrocarbon group can have a substituent selected from the group consisting of a hydroxy group, an amino group and a C1-C6 alkoxy group, and the aromatic hydrocarbon group can have a substituent selected from the group consisting of C1-C6 alkyl groups, a C5-C10 alicyclic hydrocarbon group, a hydroxy group, an amino group, and a C1-C6 alkoxy group,

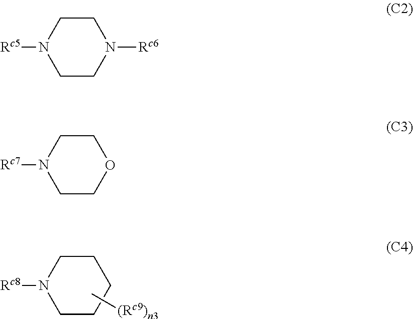

wherein R^{c5}, R^{c6}, R^{c7} and R^{c8} are defined same as R^{c1}, each of R^{c9} independently represents a C1-C6 alkyl group, a C3-C6 alicyclic hydrocarbon group, or a C2-C6 alkanoyl group, and n3 represents an integer of 0 to 8,

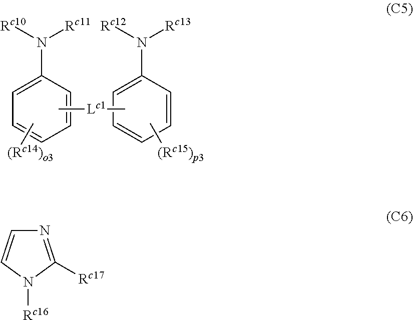

wherein each of R^{c10}, R^{c11}, R^{c12}, R^{c13} and R^{c16} is defined same as R^{c1}, each of R^{c14}, R^{c15} and R^{c17} is defined same as R^{c4},
L^{c1} represents a C1-C6 alkanediyl group, —CO—, —C(═NH)—, —S— or a combination thereof, and o3 and p3 respectively represent an integer of 0 to 3,

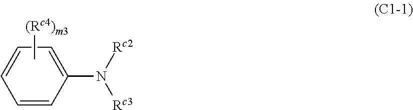

wherein R^{c2} and R^{c3} are defined as above, each of R^{c4} independently represents a C1-C6 alkyl group, a C1-C6 alkoxy group, a C5-C10 alicyclic hydrocarbon group or a C6-C10 aromatic hydrocarbon group, and m3 represents an integer of 0 to 3.
The compound represented by formula (C1) includes 1-naphthylamine, 2-naphthylamine, aniline, diisopropylaniline, 2-methylaniline, 3-methylaniline, 4-methylaniline, 4-nitroaniline, N-methylaniline, N,N-dimethylaniline, diphenylamine, hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane and 4,4′-diamino-3,3′-diethyldiphenylmethane. Among them, preferred is diisopropylaniline and more preferred is 2,6-diisopropylaniline
The compound represented by formula (C2) includes piperazine.

The compound represented by formula (C3) includes morpholine.

The compound represented by formula (C4) includes piperidine and hindered amine compounds having a piperidine skeleton as disclosed in JP 11-52575 A1.

The compound represented by formula (C5) includes 2,2′-methylenebisaniline.

The compound represented by formula (C6) includes imidazole and 4-methylimidazole.
The ammonium salt includes tetramethylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).
The compositions of the present invention comprise a solvent.

The solvent includes a glycol ether ester such as ethylcellosolve acetate, methylcellosolve acetate and propylene glycolmonomethylether acetate; an ester such as ethyl lactate, butyl acetate, amyl acetate and ethyl pyruvate; a ketone such as acetone, methylisobutylketone, 2-heptanone and cyclohexanone; and a cyclic ester such as γ-butyrolactone

In the composition of the present invention, the solvent can make the composition possible to form a uniform and flat film.

The amount of the solvent is usually 20% by weight or more, preferably 30% by weight or more, more preferably 40% by weight or more based on total amount of the composition of the present invention. The amount of the solvent is usually about 80% by weight or less, preferably 75% by weight or less, more preferably 70% by weight or less, based on total amount of the composition of the present invention.

The compositions of the present invention may comprise if necessary, a small amount of various additives such as a sensitizer, a dissolution inhibitor, other polymers, a surfactant, a stabilizer and a dye as long as the effect of the present invention is not prevented.

The compositions of the present invention can usually be prepared by mixing, in a solvent, an acid generator, Resin (A1), novolak resin, the compound represented by formula (X), and if necessary additives at a suitable ratio for the composition, optionally followed by filtrating the mixture with a filter having from 0.01 to 50 μm of a pore size.

The order of mixing these components is not limited to any specific order. The temperature at mixing the components is usually 10 to 40° C., which can be selected in view of the resin or the like. The mixing time is usually 0.5 to 24 hours, which can be selected in view of the temperature. The means for mixing the components is not limited to specific one. The components can be mixed by being stirred.

The amounts of the components in the photoresist compositions can be adjusted by selecting the amount to be used for production of them.

The composition of the present invention can provide a photoresist pattern on the substrate, and the pattern has excellent profile of its cross-section.

The compositions of the present invention are suitable for producing thick photoresist films for bumps. The compositions can provide photoresist films with thickness in the range of usually 2 to 200 μm, preferably 4 to 150 μm, more preferably 5 to 100 μm.

The photoresist film obtained by applying the composition of the present invention on a substrate, the thickness of said film being in the above-mentioned ranges, is also one aspect of the present invention.

A photoresist pattern can be produced using the composition of the present invention by the following steps (1) to (5):

(1) a step of applying the photoresist composition of the present invention on a substrate,

(2) a step of forming a photoresist film by conducting drying,

(3) a step of exposing the photoresist film to radiation,

(4) a step of baking the exposed photoresist film, and

(5) a step of developing the baked photoresist film to form a photoresist pattern.

The applying of the composition on a substrate is usually conducted using a conventional apparatus such as spin coater.

The substrate includes a silicon wafer; a quartz wafer; and other inorganic materials such as glass. The substrate may have a sensor, a circuit, a transistor, conductive materials or insulating materials such as SiO₂ and polyimide formed thereon.

The substrate may be coated with a reflect-preventing layer such as one containing hexamethyldisilazane. For forming the reflect-preventing layer, such composition for organic reflect-preventing layer as available on the market can be used.

The photoresist film is usually formed by heating the coat layer with a heating apparatus such as hot plate or a decompressor, to thereby dry off the solvent. The heating temperature is preferably 50 to 200° C., and the operation pressure is preferably 1 to 1.0*10⁵ Pa. These conditions can be selected in view of the solvent.

The thickness of the photoresist film is in the range of preferably 4 to 150 μm, more preferably 5 to 100 μm.

The photoresist film is exposed to radiation using an exposure system. The exposure is usually conducted through a mask having a pattern corresponding to the desired photoresist pattern. The exposure source includes known one, preferably g ray (wave length: 436 nm), h ray (wave length: 405 nm) and i ray (wave length: 365 nm).

Exposure through a mask makes the composition film have exposed areas and unexposed area. At the exposed area, the acid generator contained in the component layer gives an acid due to exposure energy. The acid generated from the acid generator acts on an acid-labile group of the resin, so that the deprotection reaction proceeds, resulting that the resin shows hydrophilic. Therefore, the resin becomes soluble with an alkaline solution at exposed area of the composition film. On the other hand, unexposed area of the composition film remains insoluble or poorly soluble in an aqueous alkali solution even after exposure. The solubility for an aqueous alkali solution is much different between the exposed area and unexposed area.

The step of baking of the exposed photoresist film is so called post-exposure bake, which is conducted with heating means such as hot plates. The temperature of baking of the exposed photoresist film is preferably 50 to 200° C., and more preferably 70 to 150° C. The deprotection reaction further proceeds by post-exposure bake.

The development of the baked photoresist film is usually carried out with alkaline developer using a development apparatus.

The development can be conducted by contacting the baked photoresist film into with an aqueous alkaline solution to thereby remove the film at exposed area from the substrate while remain the film at unexposed area, forming the photoresist pattern. The alkaline developer to be used may be any one of various alkaline aqueous solution used in the art. Generally, an aqueous solution of tetramethylammonium hydroxide or (2-hydroxyethyl)trimethylammonium hydroxide (commonly known as “choline”) is often used.

After development, the photoresist pattern formed is preferably washed with ultrapure water, and the remained water on the photoresist pattern and the substrate is preferably removed.

The development of the baked photoresist film can be conducted with organic solvent-containing developers to provide a negative photoresist pattern. To make a negative photoresist pattern, organic solvent-containing developers and apparatuses each known in the field of the present invention can be employed.

The composition of the present invention is suitable for producing a photoresist pattern to be used for bump production, because the composition can provide a thick photoresist film and a photoresist pattern with excellent resolution.

Bumps can be produced by the process comprising the following steps;

applying a conductive material (e.g. barrier metal) on a wafer of LSI devices to form a conductive film thereon,

applying a photoresist composition on the conductive film, and exposing the composition, followed by developing to form a desired photoresist pattern,

pattern plating using the photoresist pattern as the mold to make desired parts of conductive film exposed on the surface of the device, i.e. to form an electrode of the device, and

removing the photoresist film from the device, followed by removing therefrom the other parts of conductive film previously covered with the removed photoresist film.

The conductive material to be used for forming the conductive film includes copper (Cu) or Ti and an alloy comprising copper.

In the bump, a protective film such as SiO₂ may be formed between the substrate and the conductive layer.

The conductive material for conductive film includes a metal selected from the group consisting of nickel (Ni), tin (Sn), palladium (Pd), copper (Cu), titanium (Ti) and silver (Ag), and alloys comprising such metal.

### EXAMPLES

The present invention will be described more specifically by Examples, which are not construed to limit the scope of the present invention.

The “%” and “part(s)” used to represent the content of any component and the amount of any material used in the following examples and comparative examples are on a weight basis unless otherwise specifically noted.

Structures of compounds were determined by mass spectrometry (Liquid Chromatography: 1100 Type, manufactured by AGILENT TECHNOLOGIES LTD., Mass Spectrometry: LC/MSD Type, manufactured by AGILENT TECHNOLOGIES LTD.). Hereinafter, the value of the peak in the mass spectrometry is referred to as “MASS”.

The weight-average molecular weight of any material used in the following examples is a value determined by gel permeation chromatography [HLC-8120GPC type, Column: Three of TSKgel Multipore HXL-M with guard column, manufactured by TOSOH CORPORATION, Solvent: tetrahydrofuran, Flow rate: 1.0 mL/min., Detector: RI Detector, Column temperature: 40° C., Injection volume: 100 μL] using standard polystyrene as a standard reference material.

### Reference Example 1

To a four-necked flask with a stirring device, a reflux condenser and a thermometer, 118 g of 1,4-dioxane was added and then heated to 77° C.
Dissolved were 42.7 g of tert-butyl methacrylate, 29.8 g of methoxypolyethyleneglycol methacrylate (Trade name: light ester 130MA, Kyoeisha Chemistry Co., Ltd.; The compound represented by formula (II) where n is approximately 9), 45.2 g of methoxydiethyleneglycol methacrylate and 0.4 g of azobisisobutyronitrile in 59 g of 1,4-dioxane. The obtained solution was dropped to the heated 1,4-dioxane over 1 hour, followed by stirring them at 77° C. for 10 hours.
Then the reaction mixture was cooled and then diluted with 130 g of methanol and 92 g of propyleneglycolmethylether acetate. The diluted reaction mixture was poured into 1440 g of water to make the resin precipitate. The precipitated resin was collected by filtration and dissolved in 184 g of propyleneglycolmethylether acetate, followed by pouring the solution into a mixture of 423 g of methanol and 918 g of water to make the resin precipitate. The obtained precipitates were dissolved in propyleneglycolmethylether acetate and then concentrated to obtain 40% by weight of resin solution. The obtained resin is referred to as “Resin A1”, the weight average molecular weight of which was 110000. Resin A1 comprises the following structural units.

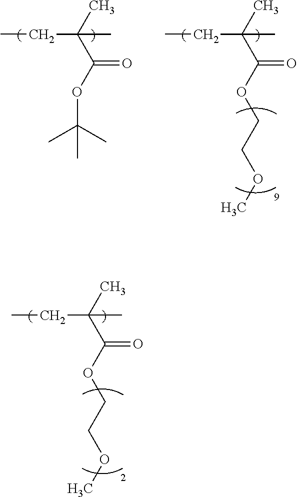

### Reference Example 2

To a four-necked flask with a stirring device, a reflux condenser and a thermometer, 413 g of 2,5-xylenol, 103.4 g of salicylaldehyde, 20.1 g of p-toluenesulfonic acid and 826.9 g of methanol were poured, and heated to make the mixture refluxed and then the temperature of the mixture was kept for 4 hours. Then the obtained mixture was cooled, and 1320 g of methylisobutylketone was fed thereto, followed by distilling it under ordinary pressure until the amount of residues became 1075 g.

Then 762.7 g of m-cresol and 29 g of 2-tert-butyl-5-methylphenol were added to the residues and heated to 65° C., followed by dropping 678 g of 37% formalin thereto over 1.5 hours while controlling the temperature of the mixture to be 87° C. at the end of dropping. Then the temperature of the mixture was kept at 87° C. for 10 hours, and then 1115 g of methylisobutylketone was added to the obtained resin solution, followed by washing it with water three times. To the washed resin solution, 3796 g of methylisobutylketone and 4990 g of n-heptane were added and heated to 60° C., and then stirred for 1 hour, followed by separating therefrom the resin solution of the bottom layer. To the separated resin solution, 3500 g of propyleneglycolmonomethylether acetate was added to dilute it, followed by distilling it under reduced pressure until the amount of solution became 1690 g.
The obtained resin is referred to as “Resin A2”, the weight average molecular weight of which was 7000.

### Reference Example 3

Mixed were 2 parts of N-BOC-leucine (Sigma Aldrich Corporation) and 20 parts of N,N-dimethylformamide to obtain a solution. To the solution, 0.6 parts of potassium carbonate and 0.18 parts of potassium iodides were added and heated to 40° C., followed by stirring it at the same temperature for 1 hour. Then 1.48 parts of 2-nitrobenzylchloride were added thereto and then stirred it at 40° C. for 4 hours. The reaction mixture was cooled to a room temperature and then 80 parts of aqueous saturated ammonium chloride solution was added thereto, followed by extracting it with 200 parts of ethyl acetate. The obtained organic layer was washed with five times, followed by removing ethyl acetate from the washed organic layer by distilling the layer under a reduced pressure to obtain 2.4 parts of compound represented by formula (X1-A).

### Reference Example 4

Mixed were 12 parts of O-benzylhydroxylamine hydrogen chloride (Tokyo Chemical Industries, Co., Ltd.), 36 parts of dioxane and 36 parts of ion exchanged water to obtain a solution. To the solution, 30 parts of triethylamine and 20.37 parts of di-tert amyl dicarbonate (Tokyo Chemical Industries, Co., Ltd.) were added and then stirred at a room temperature over night. To the obtained reaction mixture, heptane was added and then stirred and set still, followed by removing an organic layer therefrom.
To the obtained aqueous layer, 216 g of 5% aqueous hydrochloric acid solution was added, followed by newly extracting it with ethyl acetate. To the obtained organic layer, i.e., ethyl acetate layer, magnesium sulfate was added and stirred, followed by filtrating it. The filtrates were distilled under a reduced pressure to obtain 18.53 parts of compound represented by formula (X1-B).

### Reference Example 5

Mixed were 2 parts of N-BOC-phenylalanine (Sigma Aldrich Corporation) and 20 parts of N,N-dimethylformamide to obtain a solution. To the solution, 0.52 parts of potassium carbonate and 0.16 parts of potassium iodide were added and heated to 40° C., followed by stirring it at the same temperature for 1 hour. Then 1.29 parts of 2-nitrobenzylchloride were added thereto and then stirred it at 40° C. for 4 hours. The reaction mixture was cooled to a room temperature and then 80 parts of aqueous saturated ammonium chloride solution was added thereto, followed by extracting it with 200 parts of ethyl acetate. The obtained organic layer was washed with five times, followed by removing ethyl acetate from the washed organic layer by distilling it under reduced pressure to obtain 2.5 parts of compound represented by formula (X1-C).

### Examples 1 to 3 and Comparative Example 1

The following components were mixed and dissolved in the solvent as mentioned below, and further filtrated through a fluorine resin filter having pore diameter of 0.5 μm to prepare photoresist compositions. The contents of the components in each example are shown in Table 1.
The symbols recited in Table 1 represent the following component.

### <Resin>

### A1: Resin A1

### A2: Resin A2

### <Acid Generator>

B1: The compound represented by formula, trade name “NAI-105”, product by Midori Kagaku, Co., Ltd.

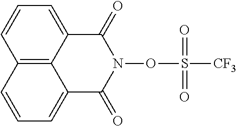 [SMILES: O=C1c2cccc3cccc(c23)C(=O)N1OS(=O)(=O)C(F)(F)F]

### <Compound>

X1-A: The compound represented by formula (X1-A)

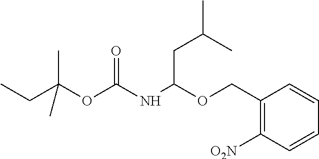 [SMILES: CCC(C)(C)OC(=O)NC(CC(C)C)OCc1ccccc1[N+](=O)[O-]]

X1-B: The compound represented by formula (X1-B)

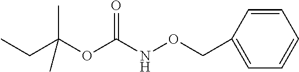 [SMILES: CCC(C)(C)OC(=O)NOCc1ccccc1]

X1-C: The compound represented by formula (X1-C)

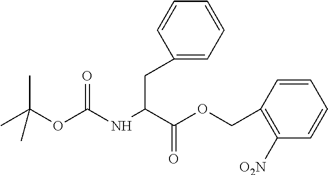 [SMILES: CC(C)(C)OC(=O)NC(Cc1ccccc1)C(=O)OCc1ccccc1[N+](=O)[O-]]

### C1: N,N-dicyclohexylmethylamine

### <Solvent>

Propyleneglycolmonomethylether acetate 28 parts

TABLE 1

| | | | |
|---|---|---|---|
| | | Acid | |
| Example | Resin | generator | Compound |
| No. | (Kind/parts) | (Kind/parts) | (Kind/parts) |

| | | | | |
|---|---|---|---|---|
| Ex. 1 | A1/7.4 | A2/5.74 | B1/0.3 | X1-A/0.05 |
| Ex. 2 | A1/7.4 | A2/5.74 | B1/0.3 | X1-B/0.05 |
| Ex. 3 | A1/7.4 | A2/5.74 | B1/0.3 | X1-C/0.05 |
| Compar. | A1/7.4 | A2/5.74 | B1/0.3 | C1/0.05 |
| Ex. 1 | | | | |

### (Preparation of Photoresist Pattern)

Over cupper substrate where copper had been vapor-deposited on a silicon wafer, each of the photoresist compositions prepared as above was spin-coated so that the thickness of the resulting film became 20 μm after drying. The cupper substrates thus coated with the respective photoresist compositions were each prebaked on a direct hotplate at 130° C. for 6 minutes.

Using an i-ray stepper (“NSR 1755i7A” manufactured by Nikon, NA=0.5), each wafer thus formed with the respective resist film was subjected to line and space pattern exposure with the exposure quantity being varied stepwise. The exposure was conducted with a mask having line and space pattern (20 μm F.T. L/S). The mask had the light-shielding parts made of chromium and the light-transmissive parts made of glass.

After the exposure, each wafer was subjected to post-exposure baking on a hotplate at 90° C. for 3 minutes, and then to paddle development for 60 seconds with an aqueous solution of 2.38 wt % tetramethylammonium hydroxide. The paddle development was conducted three times.

After the development, line and space pattern was observed with a scanning electron microscope.

### (Evaluation of Profile)

### I. Shape

The photoresist patterns were obtained by the process where the exposure was conducted at the exposure quantity of ES using the above-mentioned mask, and then each pattern was observed with a scanning electron microscope. Herein, the ES (Effective Sensitivity) means the exposure quantity that the line width of the line and space pattern of 20 μm became 1:1 after exposure through a mask having line and space pattern (line size: 20 μm).

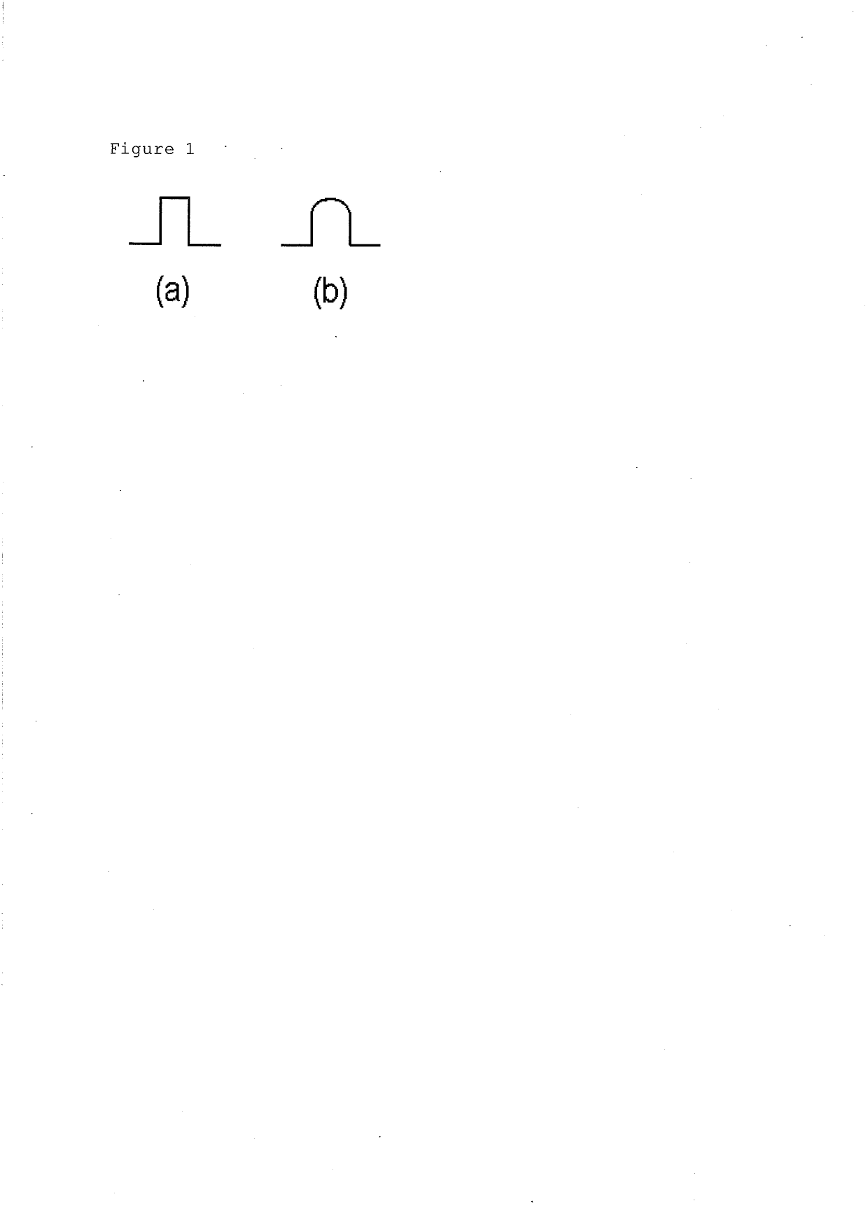

When the profile of pattern was rectangle at both top and bottom sites as shown in FIG. 1(a), it was marked by “g” (good). When the profile of pattern was a round shape at its top site, it was marked by “b” (bad) as shown in FIG. 1(b).

### II. Storage Stability

Each of the photoresist compositions was stored at 40° C. With the photoresist compositions after the storage, the photoresist patterns were made as described above, and each profile of them were evaluated as described above. Storage Stability was represented by the largest storage term of the composition whose sensitivity after storage was different by 10% or less from its sensitivity before storage.

The results of the evaluation are listed in Table 2.

TABLE 2

| | Profile | Storage Stability |
|---|---|---|
| Ex. 1 | g | At least 30 days |
| Ex. 2 | g | At least 30 days |
| Ex. 3 | g | At least 30 days |
| Comp. Ex. 1 | b | 14 days |

1. A photoresist composition comprising:
a resin which is selected from the group consisting of (meth)acryl resins and poly(hydroxystylene) resins;
a novolak resin;
an acid generator;
a compound represented by formula (X1): 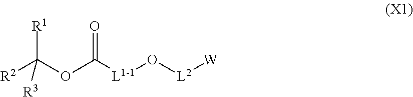
wherein R¹, R² and R³ each independently represent a hydrogen atom, a C1-C12 alkyl group, a C3-C12 alicyclic hydrocarbon group, a C6-C30 aryl group or a C7-C31 aralkyl group, or two of R¹, R² and R³ are bonded to each other to represent a C2-C10 divalent aliphatic hydrocarbon group,
L¹⁻¹ represents a group represented by formula (X1-1): 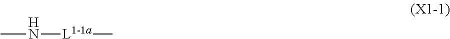
where L^{1-1a} represents a single bond, a C1-C30 hydrocarbon group which optionally has a substituent selected from a hydroxyl group, an amino group or a mercapto group and in which a methylene group is optionally replaced by an oxygen atom, a sulfur atom, an imino group, or a carbonyl group,
or a group represented by formula (X1-2): 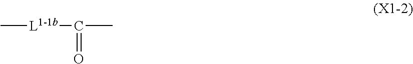
where L^{1-1b} represents a C2-C10 heterocyclic ring having one nitrogen atom bonded to —C(═O)— of the moiety —C(═O)-L¹⁻¹- in formula (X1) and having a carbon atom attached to the nitrogen atom and to the carbon atom of the carbonyl group of formula (X1-2),
L² represents a single bond, or a C1-C12 saturated aliphatic hydrocarbon group, and
W represents a C6-C30 aromatic hydrocarbon group which optionally has a substituent; and
a solvent.

2. The photoresist composition according to claim 1, wherein L¹⁻¹ represents a group represented by formula (X1-1) where L^{1-1a} represents a single bond, a C6-C10 aromatic hydrocarbon group, a C3-C10 alicylcic hydrocarbon group, or a C1-C30 aliphatic hydrocarbon group in which a methylene group is optionally replaced by an oxygen atom, a sulfur atom or a carbonyl group and in which a hydrogen atom is optionally replaced by a C6-C30 aryl group or a C7-C31 aralkyl group.

3. The photoresist composition according to claim 1, wherein the compound represented by formula (X1) is a compound represented by formula (X): 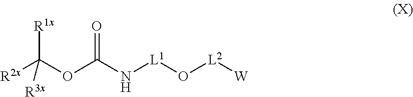
wherein L² and W are the same as defined in claim 1,
R^{1X}, R^{2 X} and R^{3 X} each independently represent a hydrogen atom, a C1-C12 alkyl group, a C3-C12 alicyclic hydrocarbon group, a C6-C30 aryl group or a C7-C31 aralkyl group, and
L¹ represents a single bond, or a C1-C30 saturated aliphatic hydrocarbon group where a methylene group is optionally replaced by an oxygen atom, a sulfur atom or a carbonyl group and where a hydrogen atom is optionally replaced by a C6-C30 aryl group or a C7-C31 aralkyl group.

4. The photoresist composition according to claim 3, wherein R^{1X}, R^{2X} and R^{3X} each independently represent a hydrogen atom, or a C1-C3 alkyl group,
L¹ represents a single bond, or a C1-C5 saturated aliphatic hydrocarbon group where a methylene group is optionally replaced by a carbonyl group and where a hydrogen atom is optionally replaced by a C7-C10 aralkyl group,
L² represents a single bond or a methylene group, and
W represents a group of formula (X2): 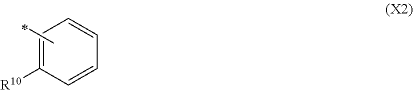
where R¹⁰ represents a hydrogen atom or a nitro group, and * is a binding position to L².

5. The photoresist composition according to claim 3 or 4, wherein the compound represented by formula (X) is one represented by formula (X1-A), (X1-B) or (X1-C).

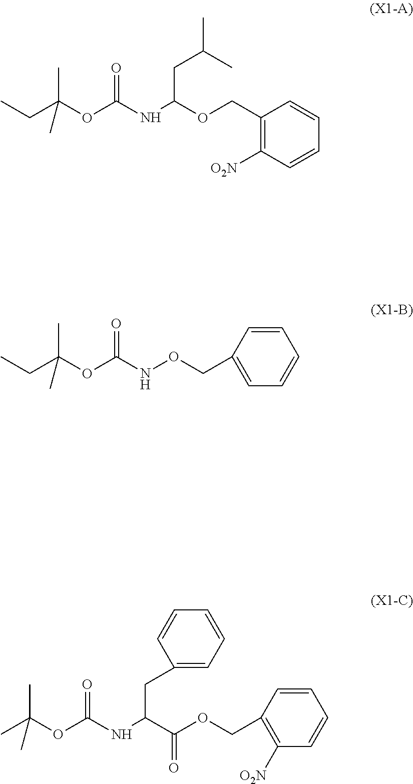 [SMILES: CCC(C)(C)OC(=O)NC(CC(C)C)OCc1ccccc1[N+](=O)[O-] ; CCC(C)(C)OC(=O)NOCc1ccccc1 ; CC(C)(C)OC(=O)NC(Cc1ccccc1)C(=O)OCc1ccccc1[N+](=O)[O-]]

6. A process for producing a photoresist pattern comprising:
(1) a step of applying the photoresist composition according to claim 1 or 2 on a substrate to form a photoresist composition film,
(2) a step of forming a photoresist film by drying the photoresist composition film,
(3) a step of exposing the photoresist film to radiation,
(4) a step of heating the photoresist film after exposing, and
(5) a step of developing the heated photoresist film.

7. The process according to claim 6 wherein the substrate comprises a conductive material containing copper or an alloy comprising the copper.

8. The process according to claim 6 wherein the photoresist film is exposed with g ray, h ray or i ray.

9. A photoresist film obtained by applying the photoresist composition according to claim 1 or 2 on a substrate, followed by drying the composition wherein the thickness of said film is in the range from 4 to 150 μm.
